(19) United States
(12) Patent Application Publication
(10) Pub. No.: US 2025/0351458 A1
(43) Pub. Date: Nov. 13, 2025

(54) LAMINATE STRUCTURE AND THIN FILM TRANSISTOR

(71) Applicant: IDEMITSU KOSAN CO.,LTD., Tokyo (JP)

(72) Inventors: Yuki TSURUMA, Chiyoda-ku, Tokyo (JP); Emi KAWASHIMA, Chiyoda-ku, Tokyo (JP); Nobuhiro IWASE, Chiyoda-ku,Tokyo (JP); Koji YAMAGUCHI, Chiyoda-ku,Tokyo (JP); Hiroyuki MIWA, Chiyoda-ku,Tokyo (JP)

(73) Assignee: IDEMITSU KOSAN CO.,LTD., Tokyo (JP)

(21) Appl. No.: 18/870,322

(22) PCT Filed: May 25, 2023
(86) PCT No.: PCT/JP2023/019467

§ 371 Date: Nov. 27, 2024

(30) Foreign Application Priority Data
May 31, 2022 (JP) 2022-089267

(51) Int. Cl. H10D 30/67; H10D 62/40; H10D 62/60; H10D 64/68

(52) U.S. Cl. CPC H10D 30/6755; H10D 30/6731; H10D 62/40; H10D 62/60; H10D 64/693

(57) ABSTRACT

Provided is a laminate structure 10, including: a crystalline oxide semiconductor film 11 containing In as a main component; and an insulating film 12 laminated in contact with the crystalline oxide semiconductor film 11, wherein the crystalline oxide semiconductor film has one or more regions continuing 3 nm or more in the film thickness direction and the region has a rare gas concentration within a range of 0.5 at % or more and less than 5 at %.

### CROSS-REFERENCE TO RELATED APPLICATIONS

The present application claims priority under 35 U.S.C. § 371 to International Patent Application No. PCT/JP2023/019467, filed May 25, 2023, which claims priority to and the benefit of Japanese Patent Application No. 2022-089267, filed on May 31, 2022. The contents of these applications are hereby incorporated by reference in their entireties.

### TECHNICAL FIELD

The present disclosure relates to a laminate structure and a thin film transistor.

### BACKGROUND ART

A thin film transistor (TFT) using an amorphous oxide semiconductor for a channel layer has been widely known (see Patent Document 1). However, the TFT has a low mobility, and hence there is a demand for improvement.

As a TFT that can obtain a high mobility characteristic as compared to the TFT using an amorphous oxide semiconductor for a channel layer, a TFT using a crystalline oxide thin film as a channel layer has been known (see, for example, Patent Document 2).

### Related Art Documents Patent Document

[Patent Document 1] JP 5118810 B2
[Patent Document 2] WO 2013/035335 A1

### SUMMARY OF INVENTION

However, with the technology of Patent Document 2, although the mobility is improved, the S value tends to be too small, making it difficult to realize an appropriate S value capable of exhibiting excellent gradation performance.

An object of the present disclosure is to provide a laminate structure that exhibits excellent gradation performance when applied to a TFT. In addition, another object of the present disclosure is to provide a thin film transistor having the laminate structure.

According to the present disclosure, the following laminate structure and the like are provided.
1. A laminate structure, including:
a crystalline oxide semiconductor film containing In as a main component; and
an insulating film laminated in contact with the crystalline oxide semiconductor film,
wherein the crystalline oxide semiconductor film has one or more regions continuing 3 nm or more in the film thickness direction and the region has a rare gas concentration within a range of 0.5 at % or more and less than 5 at %.
2. The laminate structure according to Item 1, wherein the crystalline oxide semiconductor film has one or more regions continuing 5 nm or more in the film thickness direction.
3. The laminate structure according to Item 1 or 2, wherein the rare gas is argon.
4. The laminate structure according to any one of Items 1 to 3, wherein the insulating film is any one of an oxide film containing silicon (Si) as a main component, a nitride film containing silicon (Si) as a main component, and an oxynitride film containing silicon (Si) as a main component.
5. The laminate structure according to any one of Items 1 to 4, wherein the insulating film is an oxide film containing silicon (Si) as a main component.
6. The laminate structure according to any one of items 1 to 5, wherein the crystalline oxide semiconductor film further contains Ga.
7. The laminate structure according to any one of Items 1 to 6, wherein the crystalline oxide semiconductor film further contains one or more kinds of additive elements selected from B, Al, Si, Sc, Zn, Ge, Y, Zr, Sn, Sm, and Yb.
8. The laminate structure according to any one of Items 1 to 7, wherein an atomic ratio of In with respect to all metal elements contained in the crystalline oxide semiconductor film ([In]/([In]+[all metal elements except In])×100) is 62 at % or more.
9. The laminate structure according to any one of Items 6 to 8, wherein an atomic ratio of Ga with respect to all metal elements contained in the crystalline oxide semiconductor film ([Ga]/([Ga]+[all metal elements except Ga])×100) is 30 at % or less.
10. The laminate structure according to any one of Items 7 to 9, wherein an atomic ratio of a total amount of the additive elements with respect to all metal elements contained in the crystalline oxide semiconductor film ([total amount of additive elements]/([total amount of additive elements]+[all metal elements except additive elements])×100) is 10 at % or less.
11. The laminate structure according to any one of Items 1 to 10, wherein the crystalline oxide semiconductor film has a carrier concentration of 1×10¹⁸ cm⁻³ or less.
12. The laminate structure according to any one of Items 1 to 11, wherein the crystalline oxide semiconductor film contains a crystal grain having a bixbyite structure.
13. A thin film transistor, including the laminate structure of any one of Items 1 to 12,
wherein the thin film transistor includes:
a channel layer;
a source electrode and a drain electrode each connected to the channel layer, and
a gate electrode laminated on the channel layer through intermediation of a gate insulating film,
wherein the channel layer is the crystalline oxide semiconductor film, and
wherein the gate insulating film is the insulating film.
14. The thin film transistor according to Item 13, wherein the thin film transistor is a top-gate type transistor.
15. A semiconductor element, including the laminate structure of any one of Items 1 to 12.
16. A diode, a thin film transistor, a MOSFET, or a MESFET, including the semiconductor element of Item 15.
17. An electronic circuit, including the diode, the thin film transistor, the MOSFET, or the MESFET of Item 16.
18. An electric device, an electronic device, a vehicle, or a power engine, including the electronic circuit of Item 17.

According to the present disclosure, the laminate structure that exhibits excellent gradation performance when applied to a TFT can be provided. In addition, the thin film transistor having the laminate structure can be provided.

### BRIEF DESCRIPTION OF DRAWINGS

FIG. 1 is a schematic sectional view of an example of a laminate structure of an aspect of the present disclosure.

FIG. 2 is a schematic sectional view of an example of a TFT of this aspect.

FIG. 3 is a schematic sectional view of another example of the TFT of this aspect.

FIG. 4 is a schematic sectional view of another example of the TFT of this aspect.

FIG. 5 is a schematic sectional view of a TFT produced in Example.

FIG. 6 is a schematic diagram illustrating an example of how a rare gas region exists in a crystalline oxide semiconductor film in an arbitrary cross section of a laminate structure of this aspect.

FIG. 7 is a schematic diagram illustrating another example of how a rare gas region exists in a crystalline oxide semiconductor film in an arbitrary cross section of a laminate structure of this aspect.

### DESCRIPTION OF EMBODIMENTS

The ordinal numbers “first,” “second,” and “third” as used herein are attached for avoiding confusion between constituents. Constituents without descriptions that specify the order are not limited to the numerical order of the ordinal numbers.

As used herein, the term “film” or “thin film” and the term “layer” are sometimes interchangeable with each other.

In a sintered body and an oxide thin film as used herein, the term “compound” and the term “crystal phase” are sometimes interchangeable with each other.

As used herein, the term “oxide sintered body” is sometimes simply referred to as “sintered body.” As used herein, the term “sputtering target” is sometimes simply referred to as “target.”

As used herein, the term “electrically connected” encompasses connection through an “object of some electric action.” The “object of some electric action” is not particularly limited as long as the object allows communication of electric signals between connected components. Examples of the “object of some electric action” include an electrode, a line, a switching element (e.g., a transistor), a resistive element, an inductor, a capacitor, and other elements having various functions.

As used herein, the functions of the source and drain of a transistor may be interchanged when, for example, a transistor of different polarity is adopted or the direction of a current is changed during the operation of a circuit. Accordingly, the terms “source” and “drain” as used herein may be interchangeably used.

As used herein, the term “x to y” refers to a numerical range of “x or more and y or less.” An upper limit value and a lower limit value described regarding the numerical range may be arbitrarily combined.

In addition, the present disclosure also encompasses modes obtained by combining two or more individual modes of the present disclosure described below.

### 1. Laminate Structure

A laminate structure according to an aspect of the present disclosure includes a crystalline oxide semiconductor film containing In as a main component, and an insulating film laminated in contact with the crystalline oxide semiconductor film (hereinafter referred to simply as an insulating film).

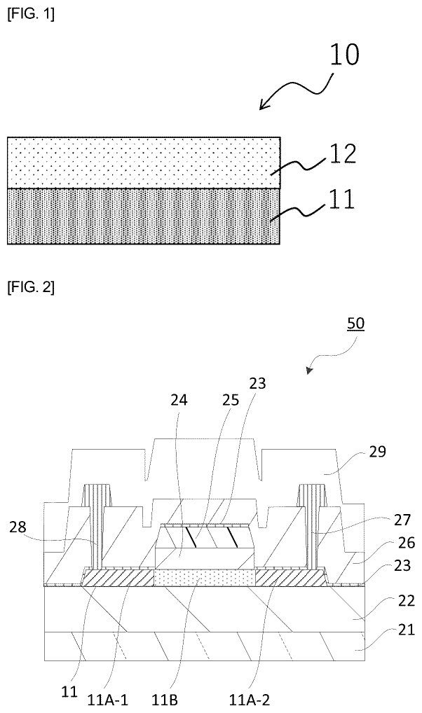

FIG. 1 is a schematic sectional view of an example of a laminate structure of an aspect of the present disclosure.

A laminate structure 10 includes a crystalline oxide semiconductor film 11, and an insulating film 12 laminated in contact with the crystalline oxide semiconductor film 11.

### (Crystalline Oxide Semiconductor Film)

The crystalline oxide semiconductor film 11 in this aspect (hereinafter simply referred to as “crystalline oxide semiconductor film”) contains an In element as a main component. The In element being a main component means that the atomic ratio of In with respect to all metal elements in the crystalline oxide semiconductor film ([In]/([In]+[all metal elements except In])×100) (atomic %: at %) is 50 at % or more. The atomic ratio of In is preferably 62 at % or more, more preferably 70 at % or more, still more preferably 80 at % or more, yet still more preferably 84 at % or more, even yet still more preferably 85 at % or more. When the In element accounts for 50 at % or more of the total number of atoms of metal elements for forming the crystalline oxide semiconductor film, a sufficiently high mobility can be exhibited when the laminate structure according to this aspect is adopted in a TFT.

The crystalline oxide semiconductor film may be formed of a single crystalline oxide semiconductor or a polycrystalline oxide semiconductor. However, it is difficult to form a uniform single crystal on a substrate having a large area in many cases, and hence it is preferred that the crystalline oxide semiconductor film be formed of a polycrystalline oxide semiconductor.

The crystalline oxide semiconductor film has one or more regions continuing 3 nm or more in the film thickness direction and the region has a rare gas concentration within a range of 0.5 at % or more and less than 5 at % (in the below description, the region may be referred to as a “rare gas region”).

The rare gas concentration of a crystalline oxide semiconductor film is the concentration of the rare gas contained in any measurement area relative to all detectable atoms contained in the measurement area.

Methods for measuring and calculating the rare gas concentration will be described in detail in Examples.

A rare gas (gaseous state) is confined in the crystalline oxide semiconductor film constituting the laminate structure of this aspect. The distribution of the rare gas in the polycrystalline oxide semiconductor film may be not necessarily uniform. Even if the rare gas is not uniformly distributed in the crystalline oxide semiconductor film, it is sufficient that there is one or more continuous, i.e., integrated, regions having a thickness of 3 nm or more in the film thickness direction (vertical direction) of the crystalline oxide semiconductor film, and a rare gas concentration of the region in the range of 0.5 at % or more and less than 5 at %.

For example, an arbitrary cross section of a laminate structure 10 of this embodiment having a crystalline oxide semiconductor film 11 and an insulating film 12 is shown in FIG. 6. In this cross section, two continuous rare gas regions 13 (13a and 13b) having a predetermined rare gas concentration and a thickness of 3 nm or more in the film thickness direction can be confirmed. The rare gas region 13 may be formed within the crystalline oxide semiconductor film 11 from the interface with the insulating film 12, for example, as the rare gas region 13a, or may be formed within the crystalline oxide semiconductor film 11 away from the interface, for example, as the rare gas region 13b.

Here, when observing any other cross section of the laminate structure 10 indicated by A-A in FIG. 6, it is not necessary that a rare gas region is observed. It is sufficient that a rare gas region is observed in any cross section, and the crystalline oxide semiconductor film 11 does not need to be continuous in the planar direction of the crystalline oxide semiconductor film 11.

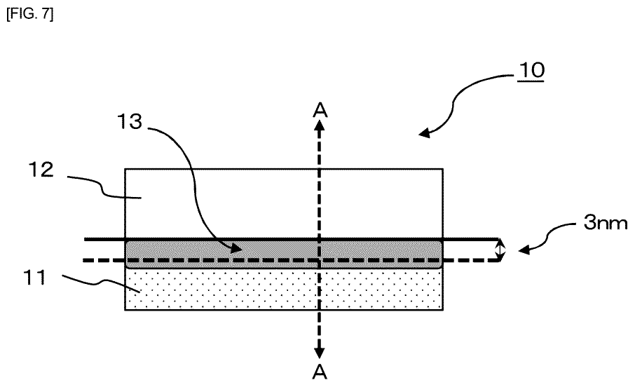

In one embodiment, as shown in FIG. 7, the rare gas region 13 has the shape of a continuous layer in the planar direction (lateral direction) of the crystalline oxide semiconductor film 11. In this case, the rare gas region is confirmed in every cross section A-A of the laminate structure 10. Here, there may be a plurality of rare gas regions 13 that are continuous in the planar direction.

The rare gas region preferably has a thickness of more than 3 nm, more preferably 5 nm or more, and further preferably 10 nm or more and 50 nm or less in the thickness direction of the crystalline oxide semiconductor film.

By the crystalline oxide semiconductor film having the rare gas region, when a laminate structure including the crystalline oxide semiconductor film is applied to a TFT, an appropriate S value (for example, about 0.8 V/dec.) can be obtained, and excellent gradation performance can be exhibited.

The rare gas concentration in the rare gas region of the crystalline oxide semiconductor film may be 0.5 at % or more, 0.51 at % or more, 0.53 at % or more, or 0.54 at % or more, and may be 5.0 at % or less, 3.0 at % or less, 2.0 at % or less, 1.5 at % or less, or 1.0 at % or less.

The rare gas concentration in the rare gas region of the crystalline oxide semiconductor film may be 0.5 to 5 at %, 0.5 to 2 at %, or 0.5 to 1 at %.

In one embodiment, the rare gas region is continuous across the entire thickness of the crystalline oxide semiconductor film. More preferably, the rare gas region is continuous over approximately half the total thickness of the crystalline oxide semiconductor film. More preferably, the rare gas region is continuous over a thickness that is approximately one-third of the total thickness of the crystalline oxide semiconductor film.

The rare gas region preferably extends to a thickness of 5 nm or more in the film thickness direction of the crystalline oxide semiconductor film.

As a result, when a laminate structure including the crystalline oxide semiconductor film is applied to a TFT, an appropriate S value (for example, about 0.8 V/dec.) can be obtained more stably, and excellent gradation performance can be obtained.

The rare gas region can be formed in a crystalline oxide semiconductor film, for example, by supplying rare gas atoms to the crystalline oxide semiconductor film from the insulating film side of a laminate structure composed of the crystalline oxide semiconductor film and the insulating film to dope the crystalline oxide semiconductor film with a rare gas element. A specific method for supplying the rare gas element to the crystalline oxide semiconductor film will be described in detail in the method for producing a laminate structure.

The type of the rare gas atom is not particularly limited, and examples thereof include Ar, He, Ne, Kr, and the like. From the viewpoint of stability in the crystalline oxide semiconductor film, Ar and He are preferable, and Ar is more preferable.

In one embodiment, the crystalline oxide semiconductor film may contain Ga in addition to In.

When the crystalline oxide semiconductor film contains Ga, the atomic ratio of Ga with respect to all metal elements in the crystalline oxide semiconductor film ([Ga]/([Ga]+[all metal elements except Ga])×100) (atomic %: at %) is preferably 30 at % or less, more preferably 20 at % or less, still more preferably 16 at % or less, yet still more preferably 15 at % or less.

When the Ga element accounts for 30 at % or less of the total number of atoms of metal elements for forming the crystalline oxide semiconductor film, a sufficiently high mobility can be exhibited when the laminate structure according to this embodiment is adopted in a TFT.

The crystalline oxide semiconductor film may contain, in addition to In, one or more elements selected from the group consisting of: H; B; C; N; O; F; Mg; Al; Si; O; S; Cl; Ar, Ca; Sc; Ti; V; Cr; Mn; Fe; Co; Ni; Cu; Zn; Ga; Ge; Y; Zr; Nb; Mo; Tc; Ru; Rh; Pd; Ag; Cd; Sn; Sb; Cs; Ba; Ln; Hf; Ta; W; Re; Os; Ir; Pt; Au; Pb; and Bi.

In one embodiment, the crystalline oxide semiconductor film may contain, in addition to In, one or more kinds of additive elements Z selected from B, Al, Si, Sc, Zn, Ge, Y, Zr, Sn, Sm, and Yb.

When the crystalline oxide semiconductor film contains the additive element Z, the atomic ratio of the total amount of the additive element Z with respect to all metal elements in the crystalline oxide semiconductor film ([total amount of additive element Z])/([total amount of additive element Z]+[all metal elements except additive element Z])×100) (atomic %: at %) is preferably 10 at % or less, more preferably 7.5 at % or less, still more preferably 5 at % or less.

When the total amount of the additive element Z is 10 at % or less of the total number of atoms of metal elements for forming the crystalline oxide semiconductor film, a sufficiently high mobility can be exhibited when the laminate structure according to this embodiment is adopted in a TFT.

In this embodiment, the crystalline oxide semiconductor film may consist essentially of elements selected from In, Mg, Al, Si, Zn, Ga, Mo, Sn, lanthanoid elements (Ln elements), and O. As used herein, the term “essentially” means that the crystalline oxide semiconductor film of the laminate structure according to this embodiment may contain any other component to the extent that the effects of the present disclosure attributed to the combination of In, Mg, Al, Si, Zn, Ga, Mo, Sn, Ln, and O described above are exhibited.

In the crystalline oxide semiconductor film according to a more preferred first mode of this embodiment, the metal elements consist of In and Ga, and the atomic ratios satisfy the following formula (11)

$$[ Ga ] / ( [ ln ] + [ Ga ] ) < 22 at \% \qquad ( 11 )$$

The crystalline oxide semiconductor film may contain inevitable impurities as the metal elements, and further F or H in addition to O. When the above-mentioned composition range is satisfied, the In ratio is increased, and crystallization to a bixbyite structure in which an In site is substituted by Ga can be achieved even by annealing at a low temperature such as 300° C. Further, when Ga having a strong bonding force with oxygen is added, oxygen deficiency after annealing is suppressed, and a film that is stable as a semiconductor can be formed.

The crystalline oxide semiconductor film according to a more preferred second mode of this embodiment consists of In, and one or more elements X selected from B, Al, Sc, Mg, Zn, Ti, Y, Zr, Mo, Sn, Hf, W, Nb, Ta, Ge, Si, La, Ce, Pr, Nd, Sm, Dy, Ho, Er, Tm, Yb, and Lu as the metal elements, and when the metal element except In is represented by X, the atomic ratios satisfy the following formula (12).

$$[ X ] / ( [ ln ] + [ X ] ) < 15 at \% \qquad ( 12 )$$

The crystalline oxide semiconductor film may contain inevitable impurities as the metal elements, and further F or H in addition to O. When the above-mentioned composition range is satisfied, the In ratio is increased, and crystallization to a bixbyite structure in which an In site is substituted by X can be achieved even by annealing at a low temperature such as 300° C. Further, when the element X having a strong bonding force with oxygen is added, oxygen deficiency after annealing is suppressed, and a film that is stable as a semiconductor can be formed.

The crystalline oxide semiconductor film according to a more preferred third mode of this embodiment consists of In, Ga, and one or more elements X selected from B, Al, Sc, Mg, Zn, Ti, Y, Zr, Mo, Sn, Hf, W, Nb, Ta, Ge, Si, La, Ce, Pr, Nd, Sm, Dy, Ho, Er, Tm, Yb, and Lu as the metal elements, and when the metal element except In and Ga is defined as an additive element X, the atomic ratios satisfy the following formulae (13) and (14).

$$[ Ga ] / ( [ ln ] + [ Ga ] + [ X ] ) < 22.5 at \% \qquad ( 13 )$$

$$[ X ] / ( [ ln ] + [ Ga ] + [ X ] ) < 8. at \% \qquad ( 14 )$$

The crystalline oxide semiconductor film may contain inevitable impurities as the metal elements, and further F or H in addition to O.

When the above-mentioned composition range is satisfied, the In ratio is increased, and crystallization to a bixbyite structure in which an In site is substituted by Ga can be achieved even by annealing at a low temperature such as 300° C. In addition, when the additive element X having a strong bonding force with oxygen is added, oxygen deficiency after annealing is further suppressed, and a film that is stable as a semiconductor can be formed.

The crystalline oxide semiconductor film according to a more preferred fourth mode of this embodiment consists of In, Sn, and one or more elements X selected from B, Al, Sc, Mg, Zn, Ti, Y, Zr, Mo, Hf, W, Nb, Ta, Ge, Si, La, Ce, Pr, Nd, Sm, Dy, Ho, Er, Tm, Yb, and Lu as the metal elements, and when the metal element except In and Sn is defined as an element X, the atomic ratios satisfy the following formulae (15) and (16).

$$[ Sn ] / ( [ ln ] + [ Sn ] + [ X ] ) < 20 at \% \qquad ( 15 )$$

$$[ X ] / ( [ ln ] + [ Sn ] + [ X ] ) < 8. at \% \qquad ( 16 )$$

The crystalline oxide semiconductor film may contain inevitable impurities as the metal elements, and further F or H in addition to O.

When the composition range as described above is satisfied, the In ratio is increased, and crystallization to a bixbyite structure in which an In site is substituted by Sn can be achieved even by annealing at a low temperature such as 300° C. Sn has a large ion radius and a large orbital overlap with In, and hence a high mobility can be held. In addition, when the additive element X having a strong bonding force with oxygen is added, oxygen deficiency after annealing is further suppressed, and a film that is stable as a semiconductor can be formed.

The crystalline oxide semiconductor film according to a more preferred fifth mode of this embodiment consists of In, Zn, and one or more elements X selected from B, Al, Sc, Mg, Ti, Y, Zr, Mo, Hf, W, Nb, Ta, Ge, Si, La, Ce, Pr, Nd, Sm, Dy, Ho, Er, Tm, Yb, and Lu as the metal elements, and when the metal element except In and Zn is defined as an element X, the atomic ratios satisfy the following formulae (17) and (18).

$$[ Zn ] / ( [ ln ] + [ Zn ] + [ X ] ) < 12 at \% \qquad ( 17 )$$

$$[ X ] / ( [ ln ] + [ Zn ] + [ X ] ) < 8. at \% \qquad ( 18 )$$

The crystalline oxide semiconductor film may contain inevitable impurities as the metal elements, and further F or H in addition to O.

When the above-mentioned composition range is satisfied, the In ratio is increased, and crystallization to a bixbyite structure in which an In site is substituted by Zn can be achieved even by annealing at a low temperature such as 300° C. When Zn is added, the film immediately after film formation can be brought into an amorphous state, and the film can be processed without any residue at the time of semiconductor patterning with an acid during the production of a TFT. Further, when the additive element X having a strong bonding force with oxygen is added, oxygen deficiency after annealing is suppressed, and a film that is stable as a semiconductor can be formed.

The content (atomic ratio) of each metal element in the crystalline oxide semiconductor film may be determined by measuring the abundance of each element by inductively coupled plasma (ICP) measurement or X-ray fluorescence (XRF) measurement. An inductively coupled plasma optical emission spectrometer (ICP-OES manufactured by Agilent) may be used for the ICP measurement. A thin film X-ray fluorescence analyzer (AZX400 manufactured by Rigaku Corporation) may be used for the XRF measurement.

In addition, the content (atomic ratio) of each metal element in the crystalline oxide semiconductor film may be analyzed, with an error accuracy of less than 2 at %, by TEM-EDS measurement using an electron microscope, ICP measurement using an inductively coupled plasma optical emission spectrometer, and SIMS analysis using a sector-type dynamic secondary ion mass spectrometer.

In one embodiment, the carrier concentration of the crystalline oxide semiconductor film is 1×10¹⁸ cm⁻³ or less, preferably 1×10¹⁷ cm⁻³ or less, more preferably 1×10¹⁶ cm⁻³ or less. With this configuration, the Vth approaches 0 V in an Id-Vg curve when a Vd of 0.1 V is applied to drive a TFT, and satisfactory performance of normally-off characteristics is exhibited.

The carrier concentration is measured by the following method.

The crystalline oxide semiconductor film is cut out into a size of 1 cm square, and an electrode is connected to each of its four corners through use of In solder to provide an element for Hall effect measurement. Then, the carrier concentration is measured. The carrier concentration is determined by performing AC Hall effect measurement through use of Model ResiTest 8400 (manufactured by TOYO Corporation) at room temperature.

Measurement conditions are as described below. The value of the carrier concentration of electrons when an F value as measurement accuracy is 0.9 or more and the absolute value of a Hall voltage phase is from 170° to 180° is adopted.

Current value: 1×10⁻¹² A to 1×10⁻³ A

Magnetic field intensity: 0.36 T

The thickness of the crystalline oxide semiconductor film is preferably 1000 nm or less, more preferably 100 nm or less, further preferably 50 nm or less, further preferably 35 nm or less, and particularly preferably 30 nm or less. When the thickness of the crystalline oxide semiconductor film is 1000 nm or less, a stable device shape can be obtained when the laminate structure of this embodiment is applied to a TFT.

In one embodiment, the thickness of the crystalline oxide semiconductor film is preferably 100 nm or less, more preferably 52 nm or less, further preferably 50 nm or less, and particularly preferably 35 nm or less.

When the thickness of the crystalline oxide semiconductor film is 100 nm or less, rare gas atoms supplied from the insulating film in the production process of the laminate structure described later are appropriately diffused into the crystalline oxide semiconductor film, and the rare gas region can be stably formed in the crystalline oxide semiconductor film.

In one embodiment, the thickness of the crystalline oxide semiconductor film is preferably 70 nm or less, more preferably 60 nm or less, even more preferably 45 nm or less, and even more preferably 35 nm or less.

When the thickness of the crystalline oxide semiconductor film is 70 nm or less, rare gas ions injected into the crystalline oxide semiconductor film by ion implantation treatment or plasma treatment are appropriately dispersed in the crystalline oxide semiconductor film in the production process of a laminate structure described later, and a rare gas region can be stably formed in the crystalline oxide semiconductor film.

On the other hand, the thickness of the crystalline oxide semiconductor film is, for example, 3 nm or more, may be 5 nm or more, or may be 8 nm or more. When the thickness of the crystalline oxide semiconductor film is 3 nm or more, high-quality crystals can be grown without being influenced by an underlayer during annealing crystallization (during formation of the crystalline oxide semiconductor film).

As used herein, the thickness is measured based on a cross-sectional TEM observation image (sometimes referred to as “cross-sectional TEM image”).

In one embodiment, the crystalline oxide semiconductor film contains a crystal grain having a bixbyite structure in its electron beam diffraction. The crystal grain having a bixbyite structure has a cubic crystal shape with satisfactory symmetry, and hence a reduction in TFT characteristic (mobility) can be suppressed even across the crystal grain boundaries.

Whether or not the crystal grain in the crystalline oxide semiconductor film has a bixbyite structure is evaluated by observing the electron beam diffraction pattern of a sample obtained by observing the cross-sectional TEM image.

Specifically, an oxide thin film area observed in the cross-sectional TEM image is irradiated with an electron beam at an irradiation area of about 100 nmφ and an acceleration voltage of 200 kV with a selected area aperture through use of an electron microscope (“Model JEM-2800” manufactured by JEOL Ltd.), and the diffraction pattern is measured with a camera length set to 2 m.

Further, in order to identify the crystal structure, the electron beam diffraction pattern simulation of the bixbyite structure of In₂O₃ is performed with electron beam diffraction simulation software ReciPro (free software ver 4.641 (2019 Mar. 4)). In the simulation, for the crystal structure data of the bixbyite structure, 14388 of Inorganic Crystal Structure Database (ICSD: Japan Association for International Chemical Information) is used, and a space group of Ia-3, a lattice constant of a=10.17700 Å, and the atomic coordinates of an In site (0.250, 0.250, 0.250), an In site (0.466, 0.000, 0.250), and an O site (0.391, 0.156, 0.380) are used.

Further, the simulation is performed with a camera length of 2 m and 11 kinds of reciprocal lattice vectors (1 0 0), (1 1 1), (1 1 0), (2 1 1), (3 1 1), (2 2 1), (3 3 1), (2 1 0), (3 10), (3 2 1), and (2 3 0) as incident electron beam directions.

The results of the diffraction points of the electron beam diffraction pattern of the oxide thin film are compared to those of the resultant simulation pattern. When the result has matched any one of the 11 kinds of simulation patterns, it is judged that the oxide thin film contains a crystal grain having a bixbyite structure.

It is desired that the crystalline oxide semiconductor film contain a crystal grain having a Bixbyite structure. However, when an electron beam diffraction pattern can be recognized in an oxide thin film area observed with an electron microscope as described above, the oxide thin film may be regarded as a crystalline oxide semiconductor film.

### (Insulating Film)

A material for forming the insulating film is not particularly limited, and any material that is generally used may be selected. In addition, a laminated film may be used. For example, SiO₂, SiNₓ, silicon oxynitride, Al₂O₃, Ta₂O₅, TiO₂, MgO, ZrO₂, Ga₂O₃, GeO₂, Nd₂O₃, La₂O₃, CeO₂, K₂O, Li₂O, Na₂O, Rb₂O, SC₂O₃, Y₂O₃, HfO₂, CaHfO₃, PbTiO₃, BaTa₂O₆, SrTiO₃, Sm₂O₃, or AlN may be used. The oxidation numbers of the respective materials may be varied.

In one embodiment, the insulating film is any one of an oxide film containing silicon (Si) as a main component, a nitride film containing silicon (Si) as a main component, and an oxynitride film containing silicon (Si) as a main component.

As a result, when rare gas diffusion from the insulating film occurs in the production process of the laminate structure described later, it becomes easier to obtain a state in which rare gas atoms are appropriately diffused into the crystalline oxide semiconductor film, and a crystalline oxide semiconductor film having the above-mentioned rare gas region can be stably obtained.

From the viewpoints of ease of availability and stability of the insulating film, the insulating film is more preferably an oxide film containing silicon (Si) as a main component.

The oxide film containing silicon (Si) as a main component means an oxide film in which the atomic ratio of silicon (Si) with respect to all cation atoms contained in the oxide film is 90 at % or more, the nitride film containing silicon (Si) as a main component means a nitride film in which the atomic ratio of silicon (Si) with respect to all cation atoms contained in the nitride film is 90 at % or more, and the oxynitride film containing silicon (Si) as a main component means an oxynitride film in which the atomic ratio of silicon (Si) with respect to all cation atoms contained in the oxynitride film is 90 at % or more.

The thickness of the insulating film is, for example, 40 nm or more, may be 50 nm or more, or may be 60 nm or more.

When the insulating film has a thickness of 40 nm or more, the rare gas region can be stably formed in the crystalline oxide semiconductor film. For example, in the production process of a laminate structure described later, in a crystalline oxide semiconductor film obtained by rare gas diffusion from an insulating film, rare gas atoms diffused into the crystalline oxide semiconductor film are unlikely to dissipate to the outside of the crystalline oxide semiconductor film, and the rare gas region can be stably formed in the crystalline oxide semiconductor film.

The upper limit of the thickness of the insulating film is not particularly limited, but is, for example, 300 nm or less, may be 200 nm or less, or may be 150 nm or less.

By setting the thickness of the insulating film to 300 nm or less, a stable device shape can be obtained when the laminate structure of this embodiment is applied to a TFT.

The insulating film 12 may be a single layer film or a laminated film. In the case of the laminated film, the suitable thickness described regarding the insulating film 12 is the thickness of the entire laminated film. When a film is obtained in the rare gas treatment step in the method of producing a laminate structure described later, the film is integrated with a layer formed thereon to function as a gate insulating film 24 of a TFT in the form of a laminated film.

### 2. Method of Producing Laminate Structure

The laminate structure of this aspect may be produced, for example, by forming an oxide thin film containing an oxide of In as a main component on a lower layer or the like for forming a TFT, such as a substrate, a buffer layer, or an insulating layer, and subjecting the oxide thin film to crystallization treatment to form a crystalline oxide semiconductor film (crystalline oxide semiconductor film formation step), and then forming an insulating film in contact with the crystalline oxide semiconductor film (insulating film formation step). In order to form a rare gas region in the crystalline oxide semiconductor film, for example, the rare gas supply treatment is performed between the formation of the crystalline oxide semiconductor film and the formation of the insulating film, or during the formation of the insulating film. The rare gas supply treatment will be described later.

A method of forming an oxide thin film containing an oxide of In as a main component is not particularly limited, but examples thereof include DC sputtering, AC sputtering, RF sputtering, ICP sputtering, reactive sputtering, ion plating, ALD, PLD, MO-CVD, ICP-CVD, a sol-gel method, a coating method, and mist CVD.

When the film formation is performed by sputtering, the film formation may be performed by a device with a planar sputtering cathode or may be performed by a device with a rotary sputtering cathode.

As an example of the method of forming the oxide thin film, the film may be produced by performing film formation by DC sputtering through use of a sputtering target including an oxide sintered body containing an oxide of In as a main component.

The atomic composition ratio of the oxide thin film obtained by the sputtering method reflects the atomic composition ratio of the oxide sintered body in the sputtering target. Accordingly, the film formation is preferably performed by using a sputtering target including an oxide sintered body having the same atomic composition ratio as the atomic composition ratio of a desired oxide thin film.

In addition, heat treatment may be performed after the formation of the oxide thin film. The step of the heat treatment is not particularly limited, but a hot air furnace, an IR furnace, a lamp annealing device, a laser annealing device, a thermal plasma device, or the like may be used.

Further, plasma oxidation treatment with N₂O or plasma oxidation treatment with O₂ may be performed after the annealing. A device for the plasma oxidation treatment is not particularly limited, but is, for example, PE-CVD.

The content of an impurity metal in the target used in the sputtering method is preferably 500 ppm or less, more preferably 100 ppm or less. The content of the impurity metal in the target may be measured by ICP or SIMS as in the crystalline oxide semiconductor film. The “impurity” contained in the target means a trace element that is mixed in a raw material or during a manufacturing process and is not intentionally added, the element having substantially no influence on the performance of each of the target and the semiconductor. The term “impurity metal” means a metal element among the elements as “impurities.”

In this embodiment, the sputtering target may consist essentially of In and an element selected from Mg, Al, Si, Zn, Ga, Mo, Sn, lanthanoid elements (Ln elements), and O. Herein, the term “essentially” means that the sputtering target may contain any other component in addition to In described above to the extent that the effects of the present disclosure attributed to the combination of Mg, Al, Si, Zn, Ga, Mo, Sn, Ln, and O are exhibited.

As in the crystalline oxide semiconductor film of the laminate structure of the present disclosure described above, the sputtering target according to a more preferred first mode of this embodiment is an oxide consisting of In and Ga as metal elements, and the atomic ratios satisfy the following formula (11).

$$[ Ga ] / ( [ ln ] + [ Ga ] ) < 22 at \%$$

The sputtering target according to a more preferred second mode is an oxide consisting of In and one or more elements X selected from B, Al, Sc, Mg, Zn, Ti, Y, Zr, Mo, Sn, Hf, W, Nb, Ta, Ge, Si, La, Ce, Pr, Nd, Sm, Dy, Ho, Er, Tm, Yb, and Lu as metal elements, and when the metal element except In is represented by X, the atomic ratios satisfy the following formula (12).

$$[ X ] / ( [ ln ] + [ X ] ) < 15 at \% \qquad ( 12 )$$

The sputtering target according to a more preferred third mode is an oxide consisting of In, Ga, and one or more elements X selected from B, Al, Sc, Mg, Zn, Ti, Y, Zr, Mo, Sn, Hf, W, Nb, Ta, Ge, Si, La, Ce, Pr, Nd, Sm, Dy, Ho, Er, Tm, Yb, and Lu as metal elements, and when the metal element except In and Ga is defined as an additive element X, the atomic ratios satisfy the following formulae (13) and (14).

$$[ Ga ] / ( [ ln ] + [ Ga ] + [ X ] ) < 22.5 at \% \qquad ( 13 )$$

$$[ X ] / ( [ ln ] + [ Ga ] + [ X ] ) < 8. at \% \qquad ( 14 )$$

The sputtering target according to a more preferred fourth mode is an oxide consisting of In, Sn, and one or more elements X selected from B, Al, Sc, Mg, Zn, Ti, Y, Zr, Mo, Hf, W, Nb, Ta, Ge, Si, La, Ce, Pr, Nd, Sm, Dy, Ho, Er, Tm, Yb, and Lu as metal elements, and when the metal element except In and Sn is defined as an element X, the atomic ratios satisfy the following formulae (15) and (16).

$$[ Sn ] / ( [ ln ] + [ Sn ] + [ X ] ) < 20 at \% \qquad ( 15 )$$

$$[ X ] / ( [ ln ] + [ Sn ] + [ X ] ) < 8. at \% \qquad ( 16 )$$

The sputtering target according to a more preferred fifth mode is an oxide consisting of In, Zn, and one or more elements X selected from B, Al, Sc, Mg, Ti, Y, Zr, Mo, Hf, W, Nb, Ta, Ge, Si, La, Ce, Pr, Nd, Sm, Dy, Ho, Er, Tm, Yb, and Lu as metal elements, and when the metal element except In and Zn is defined as an element X, the atomic ratios satisfy the following formulae (17) and (18).

$$[ Zn ] / ( [ ln ] + [ Zn ] + [ X ] ) < 12 at \% \qquad ( 17 )$$

$$[ X ] / ( [ ln ] + [ Zn ] + [ X ] ) < 8. at \% \qquad ( 18 )$$

In the sputtering target according to a preferred mode, the atomic ratio of In with respect to all metal elements contained in the sputtering target ([In]/([In]+[all metal elements except In])×100) is 62 at % or more.

In the sputtering target according to a preferred mode, the atomic ratio of Ga with respect to all metal elements contained in the sputtering target ([Ga]/([Ga]+[all metal elements except Ga])×100) (atomic %: at %) is 30 at % or less.

In the sputtering target according to a preferred mode, the total amount of the additive element Z (one or more kinds selected from B, Al, Si, Sc, Zn, Ge, Y, Zr, Sn, Sm, and Yb) with respect to all metal elements contained in the sputtering target ([total amount of additive element Z]/([total amount of additive element Z]+[all metal elements except additive element Z])×100) (atomic %: at %) is 10 at % or less.

The oxide thin film obtained by film formation by sputtering through use of the sputtering target containing indium oxide as a main component may be an amorphous oxide thin film. The amorphous oxide thin film is patterned into an island shape by photolithography, and is heated to be crystallized before the formation of a protective film. Thus, a crystalline oxide semiconductor film in which a surface crystal has a single crystal orientation can be obtained.

Respective steps are described below with the method of producing a laminate structure illustrated in FIG. 1 being used as an example.

The laminate structure of this embodiment may be produced, for example, by performing a step of forming an oxide thin film containing an oxide of In as a main component on a lower layer or the like for forming a TFT, such as a substrate, a buffer layer, or an insulating layer, and subjecting the oxide thin film to crystallization treatment to form a crystalline oxide semiconductor film (crystalline oxide semiconductor film formation step), and a step of forming an insulating film in contact with the crystalline oxide semiconductor film, followed by heat treatment, to form an insulating film (insulating film formation step).

### [Crystalline Oxide Semiconductor Film Formation Step]

### (Formation of Oxide Thin Film)

In a step of forming an oxide thin film, an oxide thin film is formed by sputtering through use of the above-mentioned sputtering target and through use of, as a sputtering gas, one or more kinds of gases selected from the group consisting of: argon; and oxygen substantially free of impurity gases, for example. In this step, it is preferred that the sputtering be performed by mounting the sputtering target on a RF magnetron sputtering device or a DC magnetron sputtering device.

The sputtering gas being “substantially free of impurity gases” means that impurity gases except the sputtering gas are not actively introduced, except for gases that are brought in by adsorbed water in association with the insertion of gases, and gases that cannot be eliminated (inevitable impurity gases), such as leakage from a chamber and adsorbed gases. Impurities are preferably eliminated from the gas (sputtering gas) to be introduced at the time of the film formation by sputtering, if possible.

The ratio of the impurity gases in the sputtering gas is preferably 0.1 vol % or less, more preferably 0.05 vol % or less. When the ratio of the impurity gases is 0.1 vol % or less, the crystallization of the oxide thin film progresses without any problem.

The purity of each of high-purity argon and high-purity oxygen, which are examples of the sputtering gas, is preferably 99 vol % or more, more preferably 99.9 vol % or more, still more preferably 99.99 vol % or more.

The gas (sputtering gas) to be introduced at the time of the film formation by sputtering is not particularly limited, but examples thereof include argon, nitrogen, oxygen, water, hydrogen, and a mixed gas containing two or more kinds of these gases.

An oxygen partial pressure in a mixed gas in the case of using argon and oxygen as an example is preferably more than 0 vol % and 50 vol % or less, more preferably more than 0 vol % and 20 vol % or less. When the oxygen partial pressure is more than 0 vol % and 50 vol % or less, the oxide thin film is easily crystallized to become a semiconductor at the time of heating. When the oxygen partial pressure is changed, the oxidation degree of the oxide thin film, that is, the crystallization degree thereof can be regulated. It is only required that the oxygen partial pressure be appropriately selected as required.

A water partial pressure in a mixed gas in the case of using argon and water as an example is preferably more than 0.03 vol % and 10 vol % or less, more preferably more than 0.03 vol % and 5 vol % or less. When the water partial pressure is more than 0.03 vol % and 5 vol % or less, the oxide thin film is easily crystallized to become a semiconductor at the time of heating. In addition, a mixed gas of hydrogen and oxygen may be used instead of water.

A crystal can be grown (to a columnar shape with respect to a lower layer, for example) by heating the oxide thin film obtained by sputtering film formation through a heat treatment step described later. When the crystalline oxide semiconductor film formed as described above is applied to a small TFT, the injection property of electron carriers becomes excellent at the time of driving, resulting in a high mobility.

The thickness of the oxide thin film (crystalline oxide semiconductor film) is preferably 1000 nm or less, more preferably 100 nm or less, further preferably 50 nm or less, further preferably 35 nm or less, and particularly preferably 30 nm or less. When the thickness of the crystalline oxide semiconductor film is 1000 nm or less, a stable device shape can be obtained when the stacked structure of this embodiment is applied to a TFT.

In the case where rare gas atoms are diffused from the insulating film into the oxide semiconductor film in a later-described insulating film formation step, the thickness of the oxide thin film (crystalline oxide semiconductor film) is preferably 100 nm or less, more preferably 52 nm or less, further preferably 50 nm or less, and particularly preferably 35 nm or less.

When the thickness of the oxide thin film (crystalline oxide semiconductor film) is 100 nm or less, in the case where rare gas diffusion from the insulating film occurs in the insulating film formation step described later, a state in which rare gas atoms are appropriately diffused into the crystalline oxide semiconductor film is easily obtained, and a crystalline oxide semiconductor film having the region of the above-mentioned rare gas concentration can be stably obtained.

In one embodiment, the thickness of the crystalline oxide semiconductor film is preferably 70 nm or less, more preferably 60 nm or less, further preferably 45 nm or less, and particularly preferably 35 nm or less.

When the thickness of the crystalline oxide semiconductor film is 70 nm or less, in the production process of a laminate structure described later, rare gas ions injected into the crystalline oxide semiconductor film by an ion implantation process or a plasma treatment are appropriately dispersed in the crystalline oxide semiconductor film, and a region having the above-mentioned rare gas concentration can be stably formed in the crystalline oxide semiconductor film.

On the other hand, the film thickness of the oxide thin film (crystalline oxide semiconductor film) is, for example, 3 nm or more, may be 5 nm or more, or may be 8 nm or more. When the thickness of the oxide thin film (crystalline oxide semiconductor film) is 3 nm or more, high-quality crystals can be grown without being influenced by the underlayer during annealing crystallization (during formation of the crystalline oxide semiconductor film).

### (Heat Treatment of Oxide Thin Film)

After the formation of the oxide thin film, heat treatment is performed. This heat treatment is sometimes referred to as “annealing.” The annealing treatment of the oxide thin film may be performed before the formation of an insulating film described later or after the formation thereof, but it is preferred to perform the annealing treatment before the formation.

When the annealing is performed before the formation of the insulating film, oxygen and hydrogen are diffused at the time of the annealing, and thus a high-quality columnar crystal is obtained. As a result, a small TFT with a low interfacial electron trap level and a high mobility is obtained after the formation of the insulating film.

The temperature of the heat treatment of the oxide thin film is preferably 250° C. or more and 500° C. or less, more preferably 280° C. or more and 470° C. or less, still more preferably 300° C. or more and 450° C. or less.

When the heat treatment temperature after the formation of the oxide thin film is 250° C. or more, the oxide thin film is easily crystallized. When the heat treatment temperature after the formation of the oxide thin film is 500° C. or less, a crystal can be prevented from abnormally growing to form a large crystal grain, and the crystal grain diameter can be controlled to be small.

A heating time in the step of heat-treating the oxide thin film is preferably 0.1 hour or more and 5 hours or less, more preferably 0.3 hour or more and 3 hours or less, still more preferably 0.5 hour or more and 2 hours or less.

Even when the heating time in the heat treatment step is less than 0.1 hour, the crystallization of the oxide thin film progresses to some extent. However, when the heating time is 0.1 hour or more, atomic diffusion easily progresses in the oxide thin film, and the oxide thin film is easily stabilized after the crystallization. Thus, a stable crystalline oxide semiconductor film is easily obtained.

When the heating time in the heat treatment step is 5 hours or less, the heat treatment step is excellent in economic efficiency.

The term “heating time” means a time (retention time) for which a predetermined highest temperature is maintained during the heat treatment.

A rate of temperature increase in the step of heat-treating the oxide thin film is preferably 2° C./min or more and 40° C./min or less, more preferably 3° C./min or more and 20° C./min or less.

When the rate of temperature increase in the step of heat-treating the oxide thin film is 2° C./min or more, the production efficiency of the oxide thin film is increased as compared to a case where the rate of temperature increase is less than 1° C./min.

When the rate of temperature increase in the step of heat-treating the oxide thin film is 40° C./min or less, at the time of the crystallization, the metal elements are uniformly diffused, and crystals in which no metal is segregated at the grain boundaries can be formed.

In addition, the rate of temperature increase in the heat treatment step is different from a value calculated from the set temperature and set time of a furnace, and is a value obtained by dividing the actual temperature of the oxide thin film by a time. The actual temperature of the oxide thin film may be determined, for example, by measuring an area within 1 cm from the oxide thin film in the furnace with a thermocouple.

The step of heat-treating the oxide thin film is preferably performed under an atmospheric atmosphere having a humidity of 10% or more at 25° C. When the heat treatment step is performed in the atmosphere having a humidity of 10% or more, hydrogen and oxygen are diffused into the film at the time of the annealing, and thus the crystallization can be accelerated.

The step of heat-treating the oxide thin film is preferably performed after the patterning of the oxide thin film. When the heat treatment is performed after the patterning, the crystallization of the oxide thin film can be accelerated while excess oxygen existing in the film during the film formation and organic substances adhering during the patterning are desorbed. As a result, a film having no organic substances or excess oxygen and having few crystal defects in the crystal grains can be formed, and an oxide thin film having few electron traps and a satisfactory conduction characteristic can be formed.

Crystal defects in the film after the step of heat-treating the oxide thin film may be evaluated, for example, by defect analysis such as cathodoluminescence (CL). When there are a large number of defects derived from oxygen, a light emission of 680 nm is strongly detected. In order to obtain an oxide thin film having few electron traps and a satisfactory conduction characteristic, it is required to adjust the film formation method and the annealing conditions so as to provide film quality in which the light emission based on the CL is prevented from being detected to the extent possible.

The step of heat-treating the oxide thin film may be performed a plurality of times. For example, the heat treatment step described above (first heat treatment step) may be performed after the patterning of the oxide thin film, and further a heat treatment step (second heat treatment step) may be performed as a final step after the production of a TFT element. The second heat treatment step is preferably performed at an annealing temperature higher than that in the first heat treatment step.

### [Rare Gas Supply Step]

Examples of a method for forming a rare gas region in a crystalline oxide semiconductor film include a method of performing a rare gas supply treatment on a crystalline oxide semiconductor film, and a method of performing a surface treatment on a crystalline oxide semiconductor film (sometimes referred to as a channel layer pretreatment) and then performing the rare gas supply treatment.

### (Channel Layer Pretreatment)

As the channel layer pretreatment, a method in which a film is formed on the crystalline oxide semiconductor film by sputtering, followed by annealing of the resulting film, and the like may be mentioned.

As the sputtering target used in the sputtering film formation for the channel layer pretreatment, those used for forming insulating films can be mentioned, and among them, SiO₂ is preferable.

The sputtering temperature during the channel layer pretreatment is not particularly limited, and the temperature during the formation of the insulating film can be employed.

The sputtering atmosphere is not particularly limited, and may contain a rare gas element or may not contain a rare gas element, or may be air.

The thickness of the film formed in the channel layer pretreatment may be 1 to 20 nm, or may be 3 to 15 nm.

When the pretreatment layer has a thickness of 1 nm or more, excessive diffusion of rare gas atoms from the film serving as a rare gas supply source into the crystalline oxide semiconductor film can be suppressed. Furthermore, by setting the thickness of the film formed in the channel layer pretreatment to 15 nm or less, diffusion of rare gas atoms from the film serving as a rare gas supply source to the crystalline oxide semiconductor film proceeds smoothly.

The temperature during annealing is not particularly limited, but is, for example, in the range of 250 to 500° C., preferably 350 to 450° C., and more preferably about 400° C.

By carrying out the channel layer pretreatment, the diffusion of rare gas atoms from the film serving as the rare gas supply source to the crystalline oxide semiconductor film proceeds smoothly.

Further, as the channel layer pretreatment, an insulating film formed by CVD may be used instead of the sputtering film formation. When the film is formed at a temperature of 240° C. or more and 450° C. or less during CVD, the subsequent heat treatment (annealing) step may be omitted.

### (Rare Gas Supply Treatment)

Examples of the rare gas supply treatment include a method of performing sputtering film formation in an atmosphere containing a rare gas element, a plasma treatment in a rare gas atmosphere, and ion implantation using rare gas ions.

When sputtering is performed in an atmosphere containing a rare gas element, the sputtering target to be used is not particularly limited, and generally, those used for forming insulating films can be used, and among them, SiO₂ is preferable.

The type of the rare gas used as the film formation atmospheric gas is not particularly limited, but examples thereof include Ar, He, Ne, and Kr. From the viewpoint of stability in the crystalline oxide semiconductor film, Ar and He are preferable, and Ar is more preferable.

The atmosphere containing a rare gas element may contain only a rare gas element, or may contain a gas such as O₂ in addition to the rare gas element.

As one example, when argon and oxygen are used as the film formation atmospheric gas, the partial pressure of argon in the mixed gas is preferably 50 volume % or more, and more preferably 70 volume %. If the argon partial pressure is 70 volume % or more and 90 volume % or less, a part of the argon gas is likely to be mixed into the insulating film during sputtering formation, and the argon gas is likely to diffuse into the crystalline oxide semiconductor film.

When argon and oxygen are used, the oxygen partial pressure in the mixed gas is preferably more than 0 volume % and not more than 50 volume %, and more preferably more than 0 volume % and not more than 40 volume %.

The thickness of the resulting film is not particularly limited, but may be 10 nm or more, 30 nm or more, 40 nm or more, 80 nm or more, or 90 nm or more. This makes it easy to mix a sufficient amount of rare gas atoms into the film obtained by sputtering, and also makes it easy to prevent the rare gas atoms that have once diffused from the film into the crystalline oxide semiconductor film from being dispersed outside the crystalline oxide semiconductor film.

The upper limit of the thickness of the obtained film is not particularly limited, but is, for example, 300 nm or less, may be 200 nm or less, or may be 150 nm or less.

By making the thickness of the obtained film 300 nm or less, a stable device shape can be obtained when the laminate structure obtained according to this embodiment is applied to a TFT.

In the case of forming the film by sputtering, it is preferable not to carry out heat treatment (annealing) after film formation.

When the heat treatment (annealing) is performed, a rare gas (For example, argon) component diffused in the oxide semiconductor film may diffuse from the oxide semiconductor film to the insulating film side and further dissipate from the surface of the insulating film.

After the film is formed in the rare gas supply process, another film (for example, a film for a gate electrode) is formed on the film without heat treatment (annealing), so that a rare gas region can be stably formed in the crystalline oxide semiconductor film.

However, even after the sputtering film formation, annealing can be performed at a temperature at which no rare gas is dissipate from the crystalline oxide semiconductor film. Specifically, the temperature is less than 400° C., preferably 300° C. or less, and more preferably 250° C. or less.

In the case of plasma treatment in a rare gas atmosphere, the type of rare gas element in the atmosphere is not particularly limited and may be one type or two or more types of rare gas elements. Among them, Ar is preferred.

Specifically, Ar plasma treatment is performed on the surface of the crystalline oxide semiconductor film directly or through another layer, so that Art ions (rare gas source) in the plasma treatment atmosphere are taken into the crystalline oxide semiconductor film.

A device for the Ar plasma treatment is not particularly limited, but for example, a dry etching device or the like can be used.

The conditions for the Ar plasma treatment are not particularly limited as long as the treatment is performed under an argon gas atmosphere. For example, when the plasma treatment is performed with a power of 10 to 500 W, and preferably 30 to 300 W, the plasma treatment is preferably performed for a treatment time of 30 to 200 seconds, and more preferably 50 to 150 seconds.

No film is formed during the plasma treatment, but an insulating film is formed after the plasma treatment.

In the case of ion implantation using rare gas ions, the type of rare gas ions used is not particularly limited, but Ar⁺ ions are preferred.

The dose amount of the rare gas ions to be implanted may be 0.1×10¹⁵ ions/cm² to 15×10¹⁵ ions/cm², 0.2×10¹⁵ ions/cm² to 12×10¹⁵ ions/cm², or 0.3×10¹⁵ ions/cm² to 10×10¹⁵ ions/cm².

When the rare gas region is formed in a crystalline oxide semiconductor film by ion implantation, the amount of implantation energy may be 0.1 keV to 1000 keV, 1 keV to 100 keV, or 5 keV to 50 keV.

In the case of ion implantation, a film is not formed, and an insulating film is formed after ion implantation into a crystalline oxide semiconductor film. In addition, in the case of ion implantation, a rare gas supply treatment can be performed on the crystalline oxide semiconductor film after the insulating film is formed.

By performing the rare gas supply treatment, the rare gas is diffused into the crystalline oxide semiconductor film, and the rare gas region is formed in the crystalline oxide semiconductor film.

The film formed in the channel layer pretreatment, the film formed in the rare gas supply treatment, and the film formed in the insulating film formation step are integrated together and function as an insulating film.

### [Insulating Film Formation Step]

The insulating film in the laminate structure of the present disclosure may be a film formed in the rare gas supply step, or may be a film formed separately on the crystalline oxide semiconductor film after the rare gas supply step, or may be composed of a film formed in the rare gas supply step and a film formed separately thereon. The film formed in the rare gas supply step and the film separately formed thereon are integrated together and function as the gate insulating film 24 in the TFT.

The film formed in the rare gas supplying step and the film separately formed thereon may be integrated into a layer other than the gate insulating film, for example, a layer that functions as a protective film or a buffer layer.

### (Formation of Insulating Film)

A method of forming the insulating film is not particularly limited. Examples of the production method include PE-CVD, ALD, PLD, MO-CVD, RF sputtering, ICP sputtering, reactive sputtering, ICP-CVD, ion plating, a sol-gel method, a coating method, and mist CVD. Tetraethoxysilane (TEOS) may be used as the kind of gas in the PE-CVD in addition to silane (SiH₄).

When the insulating film is formed by sputtering, the film is formed using a sputtering target including an oxide sintered body having an atomic composition ratio similar to that of a desired insulating film. As the sputtering target, for example, a target containing a silicon (Si)-containing compound (e.g., SiO₂, SiNₓ, or silicon oxynitride) as a main component may be used as a sputtering target.

It is preferred that one or more kinds of gases selected from the group consisting of: argon; and oxygen substantially free of impurity gases be used as a sputtering gas in the same manner as in the formation of the oxide thin film described above.

The suitable ranges of the ratio of impurity gases in the sputtering gas and the degree of purity of high-purity argon and high-purity oxygen in the sputtering gas are the same as the suitable ranges in the formation of the oxide thin film described above.

When an ion implantation treatment or an Ar plasma treatment is performed on a crystalline oxide semiconductor film as the rare gas supply treatment, the film formation atmosphere gas introduced during the formation of the insulating film does not necessarily need to contain a rare gas (for example, argon), but it is preferable that the film formation atmosphere gas contains a rare gas.

The sputtering film formation atmosphere gas is not particularly limited, but examples thereof include argon, nitrogen, oxygen, water, hydrogen, and a mixed gas containing two or more of these gases.

The preferred range of the oxygen partial pressure in the mixed gas when argon and oxygen are used is the same as that explained for the gas introduced during the sputtering film formation explained in the rare gas supply step above. The atomic ratio of silicon (Si) relative to all atoms contained in the insulating film can be adjusted by varying the oxygen partial pressure. The oxygen partial pressure may be appropriately selected as needed.

When the insulating film is formed by chemical vapor deposition (CVD), the temperature during the CVD process is preferably 240° C. or higher and 500° C. or lower, more preferably 280° C. or higher and 470° C. or lower, and even more preferably 300° C. or higher and 450° C. or lower. If the temperature during the CVD process is within the above range, an insulating film can be obtained stably.

The temperature during the CVD process means the temperature of the substrate in the CVD apparatus.

### (Heat Treatment of Insulating Film)

In the rare gas supply step, when the film formed by sputtering becomes an insulating film, it is preferable not to perform a heat treatment on the insulating film. When the heat treatment is not performed, a rare gas can be prevented from being dissipated from the crystalline oxide semiconductor film.

When a plasma treatment is adopted in the rare gas supply step, a heat treatment of the insulating film formed separately may or may not be performed, but it is preferable not to perform the heat treatment.

When the heat treatment is not performed, a rare gas can be prevented from being dissipated from the crystalline oxide semiconductor film.

When ion implantation is adopted in the rare gas supply step, a heat treatment may be performed on the insulating film formed separately.

Furthermore, when the insulating film is formed by chemical vapor deposition (CVD), the insulating film obtained may or may not be subjected to a heat treatment.

When the heat treatment of the insulating film is performed, the temperature of the heat treatment after the formation of the insulating film is preferably 250° C. or more and 500° C. or less, more preferably 280° C. or more and 470° C. or less, still more preferably 300° C. or more and 450° C. or less.

From the viewpoint of suppressing emission of a rare gas from the crystalline oxide semiconductor film, the heating temperature is preferably 400° C. or lower, and more preferably 350° C. or lower.

The heating time in the heat treatment step after the formation of the insulating film is preferably 0.1 hour or more and 5 hours or less, more preferably 0.3 hour or more and 3 hours or less, still more preferably 0.5 hour or more and 2 hours or less.

The rate of temperature increase in the heat treatment step after the formation of the insulating film is preferably 2° C./min or more and 40° C./min or less, more preferably 3° C./min or more and 20° C./min or less.

The heat treatment step after the formation of the insulating film is preferably performed under an atmospheric atmosphere having a humidity of 10% or more at 25° C.

By performing heat treatment (annealing treatment) after the formation of the insulating film, hydrogen contained in the insulating film diffuses into the crystalline oxide semiconductor film and crystal defects present on the surface of the crystalline oxide semiconductor film are terminated with hydroxy groups, so that a crystalline oxide semiconductor film with few electron traps and good conductivity can be formed.

### 3. Thin Film Transistor (TFT)

A TFT according to this aspect has the above-mentioned laminate structure of the present disclosure.

In one embodiment, the TFT includes a buffer layer, a channel layer laminated on the buffer layer in contact therewith, a source electrode and a drain electrode each connected to the channel layer, and a gate electrode laminated on the channel layer through intermediation of a gate insulating film. The channel layer is a crystalline oxide semiconductor film included in the laminate structure of the present disclosure, and the gate insulating film is an insulating film included in the laminate structure of the present disclosure.

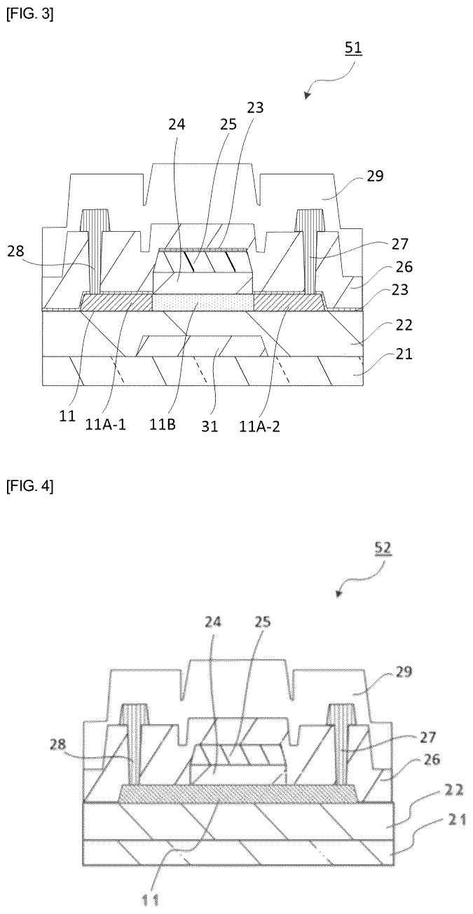

In FIG. 2 and FIG. 3 described later, there is illustrated a configuration in which both end sides of the channel layer, that is, the vicinities of regions to which the source electrode and the drain electrode are connected are low-resistance regions A of the crystalline oxide semiconductor film, and a region in contact with a lower surface of the gate insulating film is a high-resistance region B.

That is, there is illustrated a configuration in which the gate insulating film is formed on the high-resistance region B, and the source electrode and the drain electrode are formed on the low-resistance regions A.

As the configuration of the TFT according to this embodiment, for example, a configuration known in the related art may be adopted.

The TFT according to this aspect may be produced by adopting the method of producing a laminate structure described above. That is, the production method includes: a crystalline oxide semiconductor film formation step including a step of forming an oxide thin film by sputtering through use of a sputtering target and one or more kinds of gases selected from the group consisting of: argon; nitrogen; hydrogen; water; and oxygen substantially free of impurity gases as a sputtering gas (sometimes referred to as “step of forming an oxide thin film”) and a step of subjecting the oxide thin film to heat treatment (sometimes referred to as “step of heat-treating the oxide thin film”); and an insulating film formation step including a step of forming an insulating film on the crystalline oxide semiconductor film by sputtering through use of a sputtering target containing, for example, silicon dioxide as a main component (sometimes referred to as “step of forming an insulating film”) and a step of subjecting the insulating film to heat treatment (sometimes referred to as “step of heat-treating the insulating film”). Conditions and the like for each of the film formation steps and each of the heat treatment steps are as described above. A source electrode, a drain electrode, a gate electrode, and a gate insulating film may be formed by known materials and formation methods.

In the laminate structure according to one embodiment, the crystalline oxide semiconductor film has a high mobility.

By using this laminate structure in the channel layer of a TFT, high mobility and an appropriate S value (e.g., about 0.8 V/dec) can be stably obtained, and, for example, when used as a drive transistor that supplies current to an OLED, excellent gradation performance can be obtained.

Herein, the mobility at the time of the application of a Vd of 20 V is defined as a saturation mobility. Specifically, a transmission characteristic Id-Vg graph at the time of the application of a Vd of 20 V is created, and a transconductance (Gm) at each Vg is calculated. The calculation may be performed by determining the mobility through use of the formula of a saturation region.

In the following description, the current Id is a current between the source electrode and the drain electrode. The voltage Vd is a voltage (drain voltage) applied between the source electrode and the drain electrode. The voltage Vg is a voltage (gate voltage) applied between the source electrode and the gate electrode.

The shape of the thin film transistor according to this aspect is not particularly limited, but the thin film transistor is preferably a top-gate type transistor, a back channel etch type transistor, an etch stopper type transistor, or the like. In addition, those transistors may be self-aligned transistors.

In one embodiment, it is preferred that the transistors be top-gate type transistors.

Embodiments of the present disclosure are described below with reference to the drawings and the like. It should be easily understood by a person skilled in the art that the embodiments may be carried out in various manners, and their forms and details may be variously modified without departing from the gist and scope of the present disclosure. Accordingly, the present disclosure is not interpreted to be limited to the descriptions in the embodiments below.

In the drawings, a size, a layer thickness, a region, and the like are sometimes exaggerated for clarification. Accordingly, the present disclosure is not limited to the size, the layer thickness, the region, and the like shown in the drawings. The drawings include schematic illustrations of an ideal example, and the present disclosure is not limited to shapes, values, and the like shown in the drawings.

FIG. 2 is a schematic sectional view of an example of the TFT of this aspect.

A TFT 50 is a top-gate type TFT, and includes a substrate 21, a buffer layer 22, a channel layer (crystalline oxide semiconductor film) 11, an ITO layer 23, the gate insulating film (insulating film) 24, a gate electrode 25, an interlayer insulating film 26, a source electrode 27, a drain electrode 28, and a protective film 29.

The TFT 50 has a structure in which the substrate 21, the buffer layer 22, and the channel layer (crystalline oxide semiconductor film) 11 are laminated in the stated order. A high-resistance region 11B is present in the center portion of the channel layer 11, and the gate insulating film 24 (insulating film) and the gate electrode 25 are laminated on the high-resistance region 11B in the stated order. The gate insulating film 24 is an insulating film that interrupts conduction between the gate electrode 25 and the crystalline oxide semiconductor film 11.

Low-resistance regions 11A-1 and 11A-2 of the channel layer 11 are present on both sides of the high-resistance region 11B. The low-resistance regions 11A-1 and 11A-2 and the gate electrode 25 are covered with the ITO layer 23 and the interlayer insulating film 26. The ITO layer 23 is used at the time of the formation of the low-resistance regions of the channel layer 11.

Specifically, the low-resistance regions 11A-1 and 11A-2 are formed by causing a target portion of the channel layer 11 to have low resistance by performing heat treatment (annealing) in the presence of the ITO layer 23. A region that is not covered by the ITO layer 23 is maintained as the high-resistance region B.

The source electrode 27 and the drain electrode 28 are connected to the low-resistance regions 11A-1 and 11A-2, respectively, through contact holes formed in the ITO layer 23 and the interlayer insulating film 26. The source electrode 27 and the drain electrode 28 are conductive terminals for allowing a source current and a drain current to flow to the channel layer 11.

The protective film 29 is arranged so as to cover the TFT constituent layers, such as the interlayer insulating film 26, the source electrode 27, and the drain electrode 28.

The TFT of this embodiment may be modified with a known configuration.

For example, although not shown in FIG. 2, a light shield layer 31 may be formed between the substrate 21 and the buffer layer 22 in the TFT 50 as illustrated in FIG. 3, or the light shield layer 31 may be formed as an intermediate layer of the buffer layer 22 in which a plurality of layers are laminated.

FIG. 3 is a schematic sectional view of another example of the TFT of this aspect.

A TFT 51 has the same configuration as that of the TFT 50 except that the light shield layer 31 is arranged between the substrate 21 and the buffer layer 22. The light shield layer 31 is formed in order to suppress the malfunction of the TFT caused by light. The light shield layer may be connected to the source electrode 27 or may be connected to the gate electrode 25.

In addition, in FIG. 2, as an example of the TFT of the present disclosure, there is illustrated a configuration example in which both end sides of the channel layer 11, that is, the vicinities of the regions to which the source electrode 27 and the drain electrode 28 are connected are the low-resistance regions 11A of the crystalline oxide semiconductor film, and the region in contact with the lower surface of the gate insulating film 24 is the high-resistance region 11B. However, the TFT of the present disclosure is not limited to this configuration. That is, the TFT of the present disclosure may use a crystalline oxide semiconductor film having a uniform resistance value in a planar direction as the channel layer 11. In this case, the ITO layer 23 may not be formed as illustrated in FIG. 4.

FIG. 4 is a schematic sectional view of another example of the TFT of this embodiment.

A TFT 52 has the same configuration as that of the TFT 50 except that: the channel layer (crystalline oxide semiconductor film) 11 is a layer having no boundary of a resistance value (the channel layer (crystalline oxide semiconductor film) 11 is not divided into the low-resistance regions 11A and the high-resistance region 11B); and the ITO layer 23 is not formed.

In this embodiment, when the TFT is a small TFT, the crystalline oxide semiconductor film serving as the channel layer with respect to the source electrode and the drain electrode has, for example, a channel length (L length; length in the source electrode 27 and drain electrode 28 direction in a contact region between the channel layer 11 and the gate insulating layer 24 in FIG. 2) of 1 μm or more and 50 μm or less and a channel width (W length; length in a direction perpendicular to the source electrode 27 and drain electrode 28 direction in the contact region between the channel layer 11 and the gate insulating layer 24 in FIG. 2) of 1 μm or more and 80 μm or less.

The TFT of this embodiment may be modified with a known configuration.

A material for forming the substrate is not particularly limited, and any material that is generally used may be selected. There may be used, for example, a glass substrate, a ceramic substrate, a quartz substrate, or a sapphire substrate. In addition, for example, a single crystal semiconductor substrate, such as silicon or silicon carbide, a polycrystal semiconductor substrate, a compound semiconductor substrate such as silicon germanium, or a silicon on insulator (SOI) substrate may be applied, or these substrates each having a semiconductor element arranged thereon may be used as the substrate.

In addition, a flexible substrate may be used as the substrate. As a method of arranging the TFT on the flexible substrate, there is given a method of directly producing the TFT on the flexible substrate, and there is also given a method involving producing the TFT on a non-flexible substrate, then peeling the TFT, and setting the TFT on the flexible substrate. In this case, a release layer may be arranged between the non-flexible substrate and the TFT.

The buffer layer 22 may be formed of a single layer or two or more laminated layers. In addition, a metal layer may be formed between the buffer layer 22 and the substrate 21.

It is preferred that the channel layer 11 and the buffer layer 22 be in direct contact with each other as illustrated in FIG. 2.

A material for forming the buffer layer is not particularly limited, and any material that is generally used may be selected. In addition, a laminated film may be used as the buffer layer. There may be used, for example, SiO₂, SiNₓ, silicon oxynitride, Al₂O₃, Ta₂O₅, TiO₂, MgO, ZrO₂, Ga₂O₃, GeO₂, Nd₂O₃, La₂O₃, CeO₂, K₂O, Li₂O, Na₂O, Rb₂O, SC₂O₃, Y₂O₃, HfO₂, CaHfO₃, PbTiO₃, BaTa₂O₆, SrTiO₃, Sm₂O₃, or AlN. The oxidation numbers of the respective materials may be varied.

The light shield layer 31 may be connected to the source electrode 27 or may be connected to the gate electrode 25.

A material for forming the light shield layer is not particularly limited, and any material that is generally used may be selected. Specific examples thereof include metal electrodes made of Al, Ag, Cu, Cr, Ni, Co, Mo, Au, Ti, Zr, Ru, Y, Nb, Ta, and W, and metal electrodes made of alloys containing two or more kinds of these metals. In addition, a laminated electrode of two or more layers may be used.

In FIG. 3, a second buffer layer may be arranged between the light shield layer 31 and the substrate 21. A material for forming the second buffer layer is also not particularly limited, and any material that is generally used may be selected. In addition, a laminated film may be used as the second buffer layer. As a material for the second buffer layer, there may be used, for example, SiO₂, SiNₓ, silicon oxynitride, Al₂O₃, Ta₂O₅, TiO₂, MgO, ZrO₂, Ga₂O₃, GeO₂, Nd₂O₃, La₂O₃, CeO₂, K₂O, Li₂O, Na₂O, Rb₂O, SC₂O₃, Y₂O₃, HfO₂, CaHfO₃, PbTiO₃, BaTa₂O₆, SrTiO₃, Sm₂O₃, or AlN. The oxidation numbers of the respective materials may be varied.

The material described as a material for the insulating film may be used as a material for forming the gate insulating film.

Materials for forming the drain electrode, the source electrode, and the gate electrode are not particularly limited, and any materials that are generally used may be selected. Specifically, for example, there are given transparent electrodes made of ITO, IZO, ZnO, and SnO₂, metal electrodes made of Al, Ag, Cu, Cr, Ni, Co, Mo, Au, Ti, Zr, Ru, Y, Nb, Ta, and W, or metal electrodes made of alloys containing two or more kinds of these metals. In addition, a laminated electrode of two or more layers may be used.

A material for each interlayer insulating film is also not particularly limited, and any material that is generally used may be selected. In addition, a laminated film may be used as the interlayer insulating film.

For example, SiO₂, SiNₓ, silicon oxynitride, Al₂O₃, Ta₂O₅, TiO₂, MgO, ZrO₂, Ga₂O₃, GeO₂, Nd₂O₃, La₂O₃, CeO₂, K₂O, Li₂O, Na₂O, Rb₂₀, SC₂O₃, Y₂O₃, HfO₂, CaHfO₃, PbTiO₃, BaTa₂O₆, SrTiO₃, Sm₂O₃, or AlN may be used. The oxidation number of the respective materials may be varied.

Irrespective of the structure of the TFT, the protective film is preferably arranged on the drain electrode, the source electrode, and the conductive region. When the protective film is arranged, the TFT is easily improved in durability even when driven for a long period of time.

A method of producing an insulating films such as the buffer layer, the gate insulating film, or the interlayer insulating film is not particularly limited. Examples of the production method include PE-CVD, ALD, PLD, MO-CVD, RF sputtering, ICP sputtering, reactive sputtering, ICP-CVD, ion plating, a sol-gel method, a coating method, and mist CVD. Tetraethoxysilane (TEOS) may be used as the kind of gas in the PE-CVD in addition to silane (SiH₄).

For example, when an insulating film is formed by the PE-CVD, the process may become a high-temperature process. In addition, the protective film or the insulating film often contains an impurity gas immediately after the film formation, and is hence preferably subjected to the heat treatment (annealing treatment). When the impurity gas is removed by the heat treatment, a stable protective film or insulating film is obtained, which makes it easy to form a highly durable TFT.

### (Characteristics of Thin Film Transistor)

The saturation mobility of the TFT is preferably 10.0 cm²/V·s or more, more preferably 20.0 cm²/V·s or more.

When the saturation mobility of the TFT is set to 10.0 cm²/V·s or more, a higher resolution, a higher frame rate, and a larger area of a display can be achieved.

The saturation mobility of the TFT is determined from transmission characteristics in the case of the application of a drain voltage of 20 V. A method of measuring the saturation mobility of the TFT is described in detail in Examples.

The threshold voltage (Vth) is preferably −3.0 V or more and 3.0 V or less, more preferably −2.0 V or more and 2.0 V or less, still more preferably −1.0 V or more and 1.0 V or less. When the threshold voltage (Vth) is −3.0 V or more and 3.0 V or less, the threshold voltage (Vth) can be corrected to Vth=0 V by installing a Vth correction circuit on the TFT. When the TFT thus obtained is installed into a panel, a display can be driven without uneven brightness and burn-in.

The threshold voltage (Vth) may be defined as a Vg when Id=10⁻⁹ A based on the graph of transmission characteristics.

An on-off ratio is preferably 10⁶ or more, more preferably 10⁷ or more, still more preferably 10⁸ or more. When the on-off ratio is 10⁶ or more, a liquid crystal display can be driven. When the on-off ratio is 10⁸ or more, an organic EL device having a large contrast can be driven. In addition, when the on-off ratio can be set to 10¹⁰ or more, and the off-current can be set to 10⁻¹² A or less, a display element excellent in low consumption that can be driven at a low frequency of about 1 Hz can be provided.

The on-off ratio is determined by setting an off-current value to a value of Id when Vd=10 V and Vg=−10 V and setting an on-current value to a value of Id when Vd=10 V and Vg=20 V to determine a ratio [on-current value/off-current value].

The off-current value is preferably 10⁻¹⁰ A or less, more preferably 10⁻¹¹ A or less, still more preferably 10⁻¹² A or less. When the off-current value is 10⁻¹⁰ A or less, an organic EL having a large contrast can be driven. In addition, when the TFT is used as a transfer transistor or a reset transistor for a CMOS image sensor, the retention time of an image can be lengthened, and sensitivity can be improved.

A transistor with a low S value has excellent low power consumption, and therefore, in general, a transistor with a low S value tends to be considered to be good.

On the other hand, when applied as a driving transistor for an OLED or the like in which a display element is operated by current driving, the S value is preferably about 0.8 V/dec. When used as a driving transistor for an OLED, an S value of 0.3 V/dec. or less means that when the Vg value is changed by 0.3 V, the current value fluctuates by one or more orders of magnitude. Therefore, the current value must be controlled by a small amount of voltage change, which may make it difficult to control the gradation of the OLED.

For example, when used as a driving transistor for a current-driven display element such as an OLED, the S value is preferably 0.8±0.5 V/dec, more preferably 0.8±0.3 V/dec, and further preferably 0.8±0.1 V/dec. By setting the S value within the above range, it is possible to suppress the phenomenon in which the applied voltage Vg becomes high during gray scale control, which is a problem that needs to be improved more than the problem of power consumption.

The S value (Swing Factor) is a value that indicates the steepness of the drain current that rises from the off state to the on state when the gate voltage is increased from the off state. As defined by the following formula, the increment in gate voltage when the drain current increases by one order of magnitude (10 times) is taken as the S value.

$$S value = dV / dlog ( lds )$$

The smaller the S value, the steeper the rise. If the S value is large, a higher gate voltage is required to switch from on to off. The method for measuring the S value of a TFT will be described in detail in Examples.

The TFT according to this embodiment may be suitably used for solar cells, liquid crystal elements, organic electroluminescence elements, inorganic electroluminescence elements, and other display elements, and power semiconductor elements, touch panels, and other electronic devices.

The thin film transistor according to this embodiment may be applied to various integrated circuits including a field effect transistor (MOSFET or MESFET), a logic circuit, a memory circuit, and a differential amplification circuit, and the various integrated circuits may be applied to an electronic device, an electric device, a vehicle, a power engine, and the like. Further, the thin film transistor according to this embodiment may be applied not only to the field effect transistor but also to an electrostatic induction transistor and a Schottky barrier transistor.

The thin film transistor according to this embodiment may be suitably used for a display device such as a portable or in-vehicle display device, a solid-state image sensor, and the like. Further, the thin film transistor according to this embodiment may also be suitably used as a transistor for a flat panel detector for an X-ray image sensor for medical use.

In addition, the crystalline oxide semiconductor film according to this embodiment may be applied to a Schottky diode, a resistance change type memory, and a resistive element.

### EXAMPLES

The present disclosure is specifically described by way of Examples. The present disclosure is not limited to Examples.

### [Production of Self-Aligned Top-Gate Structure Small TFT]

### Example 1

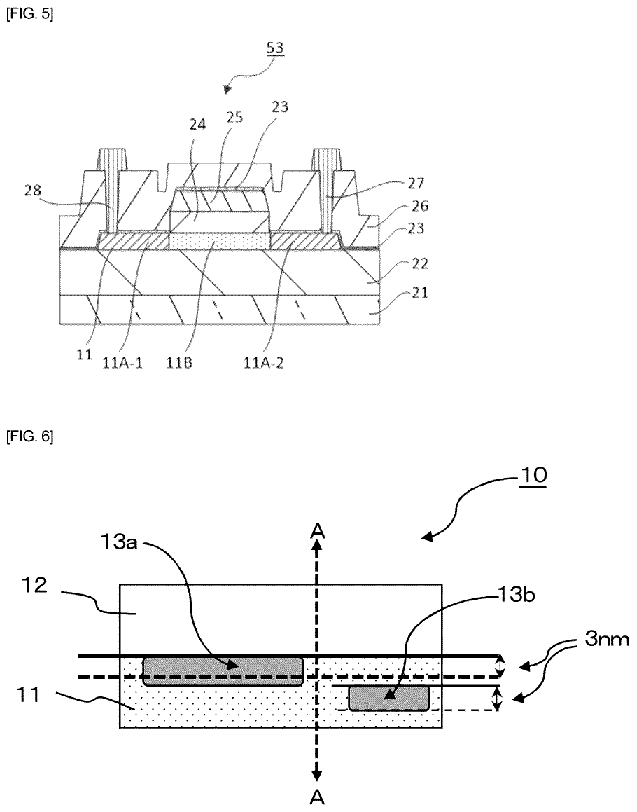

A thin film transistor (TFT) 53 illustrated in FIG. 5 was produced through the following steps. The TFT 53 has the same configuration as that of the TFT 50 illustrated in FIG. 2 except that the protective layer 29 is absent.

### (1) Formation of Buffer Layer 22

A SiOₓ layer (buffer layer 22) having a thickness of 300 nm was formed on an alkali-free glass substrate 21 (EAGLE XG manufactured by Corning Incorporated) having a diameter of 4 inches by sputtering through use of a sputtering target of SiO₂. Sputtering conditions are as described below.
Substrate temperature: 25° C.
Ultimate pressure: 8.5×10⁻⁵ Pa
Atmospheric gas: Ar
Sputtering pressure (total pressure): 0.4 Pa
Input voltage: RF 300 W
Distance between substrate(S) and target (T): 70 mm

### (2) Formation of Oxide Thin Film

Next, a channel layer was formed by sputtering through use of an oxide sputtering target obtained from a raw material mixture having a loaded composition ratio shown in Table 1-1. A metal composition ratio (unit: at %) in the oxide sputtering target is shown in Table 1-1.

Film formation conditions in the sputtering and the thickness of the channel layer are shown in Table 1-1. Sputtering conditions except those shown in Table 1-1 are as described below.
Substrate temperature: 25° C.
Ultimate pressure: 1.0×10⁻⁴ Pa
Atmospheric gas: mixed gas of Ar and H₂O
Sputtering pressure (total pressure): 0.5 Pa
Input voltage: DC 300 W
Distance between substrate(S) and target (T): 70 mm

### (3) Formation of Channel Layer 11

Next, the oxide thin film was patterned into an island shape by photolithography to form the channel layer 11. First, a film of a photoresist was formed on the oxide thin film. AZ1500 (manufactured by AZ Electronic Materials SA) was used as the photoresist. The film was exposed to light through a photomask in which a pattern was formed. After the exposure, development was performed with tetramethylammonium hydroxide (TMAH). After the development, the oxide thin film was etched with oxalic acid (ITO-06N manufactured by Kanto Chemical Co., Inc.). After the etching, the photoresist was peeled off. Thus, a substrate 21 with a patterned oxide thin film (channel layer 11) was obtained.

### (4) Annealing

Next, the substrate having the channel layer 11 formed thereabove was placed in a furnace. The temperature inside the furnace was increased to 350° C. at 10° C./min in the atmosphere, and was then held for 1 hour. After the temperature inside the furnace was held at 350° C. for 1 hour, the furnace was allowed to cool naturally. After the temperature inside the furnace returned to room temperature, the substrate was removed from the furnace.

### (5) Channel Layer Pretreatment

Next, the channel layer 11 was subjected to pretreatment by the following method.

First, a SiOₓ layer (pretreated film) having a thickness of 10 nm was formed by sputtering through use of a sputtering target of SiO₂.

The SiOₓ layer (pretreated layer) constitutes the gate insulating film 24 together with a 100 nm-thick SiOₓ layer formed in “(7) Rare Gas Supply Treatment” described later.
Sputtering conditions are as described below.
Substrate temperature: 25° C.
Ultimate pressure: 8.5×10⁻⁵ Pa
Atmospheric gas: mixed gas of Ar+O₂ (O₂ flow rate: 30%)
Sputtering pressure (total pressure): 0.4 Pa
Input voltage: RF 300 W
Distance between substrate(S) and target (T): 70 mm

The thickness of the SiOₓ layer (pretreated layer) formed by the sputtering is shown in the row of “Pretreatment method” in Table 1-1.

(6) Annealing after Pretreatment

Next, the substrate on which the SiOₓ layer was formed was placed in a furnace. The temperature inside the furnace was increased to 400° C. at 10° C./min in the atmosphere, and was then held for 1 hour. After the temperature inside the furnace was held at 400° C. for 1 hour, the furnace was allowed to cool naturally. After the temperature inside the furnace returned to room temperature, the substrate was removed from the furnace.

### (7) Rare Gas Supply Treatment

Next, a SiOₓ layer (rare gas supply source) having a thickness of 100 nm was formed by sputtering through use of a sputtering target of SiO₂. Sputtering conditions are as described below.
Substrate temperature: 25° C.
Ultimate pressure: 8.5×10⁻⁵ Pa
Atmospheric gas: mixed gas of Ar+O₂ (O₂ flow rate: 30%)
Sputtering pressure (total pressure): 0.4 Pa
Input voltage: RF 300 W
Distance between substrate(S) and target (T): 70 mm

In Tables, “SiO₂, Art” in the “Rare gas source” column indicates that the SiO₂ layer formed by sputtering incorporates a portion of the Ar gas that was present as the sputtering film forming atmosphere gas, so that the SiO₂ layer contains it as Art ions.

As a result, the SiOₓ layer (thickness: 100 nm) formed in this step is formed, and is integrated with the SiOₓ layer (thickness: 10 nm) formed in the above-mentioned “(5) Channel Layer Pretreatment” to become the gate insulating film 24. The total thickness of the gate insulating film 24 was 110 nm.

The thickness of the SiOₓ layer formed by sputtering is shown in the column “Rare gas supply amount” in Table 1-1.

### (8) Formation of Gate Electrode 25

Next, a Mo film having a thickness of 150 nm was formed through use of a sputtering target of Mo. Sputtering conditions are as described below.
Substrate temperature: 25° C.
Ultimate pressure: 8.5×10⁻⁵ Pa
Atmospheric gas: Ar
Sputtering pressure (total pressure): 0.4 Pa
Input voltage: DC 100 W
Distance between substrate(S) and target (T): 70 mm

### (9) Patterning of Gate Electrode 25 and Gate Insulating Film 24

Next, the Mo film and the gate insulating film 24 were patterned into an island shape by photolithography. First, a film of a photoresist was formed on the Mo film. AZ1500 (manufactured by AZ Electronic Materials SA) was used as the photoresist. The film was exposed to light through a photomask with a pattern formed with a width of 10 μm. After the exposure, development was performed with tetramethylammonium hydroxide (TMAH). After the development, a gate electrode 25 was formed by etching the Mo film with a mixed acid of phosphoric acid, nitric acid, and acetic acid (phosphoric-acetic-nitric acid (PAN).

Then, the gate insulating film 24 was etched with buffered hydrofluoric acid (BHF) and patterned into an island shape.

Next, after the photoresist was peeled off, a region in which the channel layer 11 was exposed was etched by a thickness of 10 nm through use of oxalic acid (ITO-06N manufactured by Kanto Chemical Co., Inc.), followed by cleaning.

The dimensions of a portion in which the resultant gate electrode layer 25 and gate insulating film 24 overlapped with the channel layer 11 were a width of 10 μm by a length of 20 μm.

### (10) Low-resistance Treatment

Low-resistance regions A (11A-1 and 11A-2) were formed in the channel layer 11 by self-alignment using the gate electrode 25. An ITO layer 23 having a thickness of 2 nm was formed through use of a sputtering target of ITO. Sputtering conditions are as described below.
Substrate temperature: 25° C.
Ultimate pressure: 8.5×10⁵ Pa
Atmospheric gas: mixed gas of Ar+O₂ (O₂ flow rate: 2%)
Sputtering pressure (total pressure): 0.4 Pa
Input voltage: DC 50 W
Distance between substrate(S) and target (T): 70 mm

Next, the substrate after the low-resistance treatment was placed in a furnace. The temperature inside the furnace was increased to 350° C. at 10° C./min in the atmosphere, and was then held for 1 hour. Thus, the substrate was annealed. After the temperature inside the furnace was held at 350° C. for 1 hour, the furnace was allowed to cool naturally. After the temperature inside the furnace returned to room temperature, the substrate was removed from the furnace.

### (11) Formation of Interlayer Insulating Film 26

Next, a SiOₓ layer (interlayer insulating film 26) having a thickness of 150 nm was formed by sputtering through use of a sputtering target of SiO₂. Sputtering conditions are as described below.
Substrate temperature: 25° C.
Ultimate pressure: 8.5×10⁻⁵ Pa
Atmospheric gas: mixed gas of Ar+O₂ (O₂ flow rate: 30%)
Sputtering pressure (total pressure): 0.4 Pa
Input voltage: RF 300 W
Distance between substrate(S) and target (T): 70 mm

### (12) Formation of Contact Hole in Interlayer Insulating Film 26

The substrate having the interlayer insulating film 26 formed thereabove was coated with a photoresist AZ1500 (manufactured by AZ Electronic Materials SA) and exposed to light through a photomask. After that, development was performed with tetramethylammonium hydroxide (TMAH). After the development, a contact hole having a width of 12 μm and a length of 18 μm was formed with buffered hydrofluoric acid (BHF).

### (13) Formation of Source Electrode 27 and Drain Electrode 28

The source electrode 27 and the drain electrode 28 were patterned by a lift-off process through use of an image reversal resist AZ5214 and a photomask. The image reversal resist AZ5214 was exposed to light through a photomask. The resist was subjected to a reversal baking step, and was then subjected to full exposure and development with TMAH. A Mo layer having a thickness of 150 nm was formed on the substrate with the patterned resist under the following sputtering conditions.
Substrate temperature: 25° C.
Ultimate Pressure: 8.5×10⁻⁵ Pa
Atmospheric gas: Ar
Sputtering pressure (total pressure): 0.4 Pa
Input voltage: DC 100 W
Distance between substrate(S) and target (T): 70 mm

After that, the substrate having the Mo layer formed thereabove was lifted off in acetone. Thus, the source electrode 27 and the drain electrode 28 were patterned.

### (14) Final Annealing

Finally, the resultant was annealed at 300° C. for 1 hour in a N₂ atmosphere to provide a self-aligned top-gate structure small TFT.

The production conditions for the TFT are summarized in Tables 1-1 to 1-3 and 2.

### Example 2

A TFT was produced in the same manner as in Example 1 except that the thickness of the channel layer formed in “(2) Formation of Oxide Thin Film” was changed as shown in Table 1-1.

### Example 3

A TFT was produced in the same manner as in Example 1 except that after performing “(7) Rare Gas Supply Treatment”, and before performing “(8) Formation of Gate Electrode 25”, the substrate on which the SiOₓ layer (rare gas supply source) was formed was annealed.

The substrate on which the SiOₓ layer (rare gas supply source) was formed was annealed by the following method.

First, the substrate having a SiOₓ layer (rare gas supply source) formed thereon was placed in a furnace, and the temperature was raised to 200° C. at a rate of 10° C./min in the atmosphere, and then held for 1 hour. The inside of the furnace was kept at 200° C. for 1 hour, and then allowed to cool naturally. After the temperature inside the furnace returned to room temperature, the substrate 21 was taken out of the furnace.

### Example 4

A TFT was produced in the same manner as in Example 1 except that “(5) Channel Layer Pretreatment” was not performed.

In Example 4, the SiOₓ layer having a thickness of 100 nm formed in “(7) Rare Gas Supply Treatment” alone constitutes the gate insulating film 24.

### Example 5

A TFT was produced in the same manner as in Example 1 except that the thickness of the SiOₓ layer (rare gas supply source) formed in “(7) Rare Gas Supply Treatment” was changed as shown in Table 1-1.

The SiOₓ layer (rare gas supply source) functions as the gate insulating film 24 of the TFT together with the 10 nm-thick SiOₓ layer (pretreatment layer) formed in “(5) Channel Layer Pretreatment” and the 50 nm-thick SiOₓ layer formed in “(7′) Formation of Gate Insulating Film 24” described below.

Next, after performing “(7) Rare Gas Supply Treatment”, and before performing “(8) Formation of Gate Electrode 25”, “(7′) Formation of Gate Insulating Film 24” was performed by the method described below (chemical vapor deposition (CVD) method).

First, the substrate after “(7) Rare Gas Supply Treatment” was set in a plasma CVD apparatus, the substrate was held at 350° C., and SiH₄ was introduced at 2 sccm, N₂O at 100 sccm, and N₂ at 120 sccm at a pressure of 110 Pa to form a SiOₓ layer with a thickness of 50 nm.

As a result, a SiOₓ layer (50 nm thick) is formed in this step, which is integrated with the 10 nm thick SiOₓ layer (pretreatment layer) formed in the above “(5) Channel Layer Pretreatment” and the 50 nm thick SiOₓ layer (Si supply source) formed in “(7) Rare Gas Supply Treatment” to form the gate insulating film 24. The total thickness of the gate insulating film 24 became 110 nm.

### Examples 6 to 7

Each TFT was produced in the same manner as in Example 1 except that in “(7) Rare Gas Supply Treatment”, the film formation atmosphere gas was changed to one shown in the “Film formation atmosphere gas or injection gas” column in Table 1-1.

In Examples 6 and 7, the O₂ flow rate of each film formation atmosphere gas was set to 30%.

### Example 8

In the “(7) Rare Gas Supply Treatment”, Ar plasma treatment was performed using a dry etching apparatus instead of film formation by sputtering. The plasma treatment was performed under conditions of an Ar gas atmosphere, a power of 100 W, and a treatment time of 100 seconds.

The treatment time for the Ar plasma treatment is shown in the “Rare gas supply amount” column of Table 1-2.

In the table, “Art” in the “Rare gas supply source” column indicates that Art ions are supplied to the channel layer as the rare gas supply source by Ar plasma treatment.

Next, after “(7) Rare Gas Supply Treatment”, and before “(8) Formation of Gate Electrode 25”, “(7′) Formation of Gate Insulating Film 24” was performed by the method (sputtering) described below.

First, a SiOₓ layer having a thickness of 100 nm was formed by sputtering using a SiO₂ sputtering target under the following sputtering conditions:
Substrate temperature: 25° C.
Ultimate pressure: 8.5×10⁻⁵ Pa
Atmospheric gas: mixed gas of Ar and O₂ (O₂ flow rate: 30%)
Sputtering pressure (total pressure): 0.4 Pa
Input voltage: RF 300 W
Distance between substrate(S) and target (T): 70 mm

In Example 8, the SiOₓ layer having a thickness of 100 nm formed in “(7′) Formation of Gate Insulating Film 24” after “(7) Rare Gas Supply Treatment” constitutes the gate insulating film 24.

The remaining steps were the same as in Example 4 to produce a TFT.

### Examples 9 to 10

In the “(7) Rare Gas Supply Treatment” of Example 1, Art ions were implanted into the channel layer 11 instead of the film formation by sputtering. The ion implantation was carried out under the condition of 50 keV using an ion implantation apparatus.

The dose amount of Art ions by ion implantation is shown in the column of “Rare gas supply amount” in Table 1-2.

Next, after performing “(7) Rare Gas Supply Treatment”, and before performing “(8) Formation of Gate Electrode 25”, “(7′) Formation of Gate Insulating Film 24” was performed by sputtering in the same manner as in Example 8 to form a SiOₓ layer having a thickness of 100 nm.

As a result, a SiOₓ layer (thickness 100 nm) was formed in this step, and is integrated with the SiOₓ layer (thickness 10 nm) formed in the above “(5) Channel Layer Pretreatment” to form the gate insulating film 24. The total thickness of the gate insulating film 24 became 110 nm.

Next, prior to “(8) Formation of Gate Electrode 25”, the substrate on which the gate insulating film 24 was formed was annealed under the conditions shown in Table 1-2.

The substrate on which the gate insulating film 24 was formed was annealed in the same manner as the substrate on which the SiOₓ layer (rare gas supply source) of Example 3 was formed, except that the highest temperature was changed to the temperature shown in Table 1-2.

The remaining steps were the same as in Example 1 to fabricate a TFT.

### Example 11

A TFT was produced in the same manner as in Example 10 except that the thickness of the channel layer formed in “(2) Formation of Oxide Thin Film” was changed as shown in Table 1-2.

### Examples 12 to 18

Each TFT was produced in the same manner as in Example 1 except that in “(2) Formation of Oxide Thin Film”, the composition ratio of the sputtering target used in forming the channel layer, and the oxygen partial pressure and water pressure of the film formation atmosphere gas during the formation of the channel layer were changed as shown in Tables 1-2 to 1-3, respectively.

### Reference Example 1

A TFT was produced in the same manner as in Example 1 except that in “(7) Rare Gas Supply Treatment”, the deposition atmosphere gas was changed to He and O₂ shown in the “Film formation atmosphere gas or injected gas” column in Table 1-3.

### Comparative Example 1

A TFT was produced in the same manner as in Example 3 except that the highest annealing temperature of the substrate on which the SiOₓ layer (Si supply source) was formed was changed as shown in Table 1-3.

The TFTs obtained in the Examples, Reference Example, and Comparative Example were evaluated as follows. The results are shown in Tables 1-1 to 1-3. In the tables, “E+XX” means “×10^{XX}”.

### (A) Evaluation Regarding Laminate Structure of TFT

### (1) Average Rare Gas Concentration in Channel Layer (Crystalline Oxide Semiconductor Film)

The average rare gas concentration was measured by transmission electron microscopy-energy dispersive X-ray spectroscopy (TEM-EDX).

The measurement of the average Si concentration in the channel layer (crystalline oxide semiconductor film) by the TEM-EDX was performed as described below.

First, the TFT obtained in each of Examples and Comparative Examples was processed with a focused ion beam (FIB) at an acceleration voltage of from 20 kV to 30 kV with a composite beam processing and observation device (“JIB-4700F” manufactured by JEOL Ltd.). After that, a thin film sample for cross-sectional TEM observation was picked up by a micro-sampling method at an acceleration voltage of 40 kV with a focused ion beam (FIB) processing and observation device (“FB-2100” manufactured by Hitachi High-Technologies Corporation).

Thin film samples for cross-sectional TEM observation were prepared as thin films that included the entire area in the thickness direction (laminating direction of the TFT) of the channel layer, and were prepared so that they had the same film thickness (film thickness: 60 to 80 nm) in all Examples and Comparative Examples.

The “average rare gas concentration in the crystalline oxide semiconductor film” in Tables 1-1 to 1-3 is a value calculated by arithmetically averaging the rare gas concentrations obtained at each measurement point over the entire film thickness in the above-described EDX line analysis.

### (2) Thickness of Rare Gas Region in Crystalline Oxide Semiconductor Film

The thin film sample for cross-sectional TEM observation was subjected to cross-sectional TEM observation, and EDX line analysis was performed in the film thickness direction from the buffer layer 22 side to the gate insulating film 24 side for a field of view including the channel layer (crystalline oxide semiconductor film) at a central location of the channel layer (crystalline oxide semiconductor film).

The EDX analysis was performed with an energy dispersive X-ray analyzer (“JED-2300T” manufactured by JEOL Ltd.) under the following conditions.
Acceleration voltage: 200 kV
Measurement mode: STEM mode
Spot diameter: 0.16 nm
Measurement interval: 1 nm

The EDX analysis was performed by selecting all elements detectable by the device as the elements to be detected (detectable elements), and performing a line analysis in the film thickness direction of the channel layer (crystalline oxide semiconductor film) using the sum of all selected elements as the denominator and the sum of rare gas elements (Ne, Ar, Kr, Xe, Rn) as the numerator.

The rare gas concentration was calculated by automatically calculating the EDX spectrum intensity obtained by EDX line analysis using the initial setting values by the dedicated software of the energy dispersive X-ray analyzer (manufactured by JEOL Ltd., “JED-2300T”).

The rare gas concentration was calculated for each measurement spot in the measurement field of view, and the film thicknesses of regions in the crystalline oxide semiconductor film that are continuous in the film thickness direction and have a rare gas concentration in the range of 0.5 at % or more and less than 5 at % are shown in the column “Thickness of rare gas region in crystalline oxide semiconductor film” in Tables 1-1 to 1-3.

In addition, the channel layer (crystalline oxide semiconductor film) region in the TFT was subjected to concentration analysis by the above-mentioned EDX line analysis, with the sum of all selected elements as the denominator and each cationic element contained in the channel layer (crystalline oxide semiconductor film) as the numerator, and the region was determined to have the largest In concentration among the cationic concentrations.

Note that He contained in the channel layer cannot be detected by TEM-EDX. Therefore, for Reference Example 1, instead of measurement by TEM-EDX, the crystalline oxide semiconductor film was analyzed by a sector-type dynamic secondary ion mass spectrometer SIMS (IMS 7f-Auto, manufactured by AMETEK Corporation) to identify He from the mass spectrum of each element. By the use of this method, it was confirmed that He was contained in the thin film sample taken from the TFT of Reference Example 1.

### (B) Evaluation Regarding Characteristics of TFT

The resultant TFT was measured with a semiconductor parameter analyzer (“B1500” manufactured by Agilent) at room temperature under a light-shielding environment (inside a shield box). A drain voltage (Vd) of 20 V was applied. A current value Id was measured at a gate voltage (Vg) of from −5 V to 20 V in increments of 0.1 V for the application of the Vd. Thus, Id-Vg characteristics were obtained.

Various parameters calculated from the Id-Vg characteristics are shown in Tables 1-1 to 1-3. A calculation method for each parameter is as described below.

### (a) S Value

The S value and threshold voltage (Vth) were evaluated from the graph of each Id-Vg characteristic. Specifically, in the current value Id range of 10⁻¹¹ to 10⁻¹⁰ [A], the value obtained by the following formula (d) was calculated as the S value.

$$S = \frac{Δ Vg}{Δ ( log Id )} \qquad ( d )$$

### (b) Initial Characteristics

The initial characteristics were obtained from the Id-Vg characteristics by measuring the current value Id in 0.1 V steps from the gate voltage (Vg) of −5 V to 20 V in response to the application of Vd. The Vg voltage value at which the current Id exceeded 10⁻⁹ A was defined as the on-voltage Vₒₙ, and the initial characteristics when Vₒₙ was 0±0.5 V were marked as “∘”.

TABLE 1-1

| | | | Example 1 | Example 2 | Example 3 | Example 4 | Example 5 | Example 6 | Example 7 |
|---|---|---|---|---|---|---|---|---|---|
| Sputtering | Loaded composition ratio | In₂O₃ | 89.0 | 89.0 | 89.0 | 89.0 | 89.0 | 89.0 | 89.0 |
| target | [mass %] | Ga₂O₃ | 9.8 | 9.8 | 9.8 | 9.8 | 9.8 | 9.8 | 9.8 |
| | | Other additive elements | Al₂O₃ 1.2 | Al₂O₃ 1.2 | Al₂O₃ 1.2 | Al₂O₃ 1.2 | Al₂O₃ 1.2 | Al₂O₃ 1.2 | Al₂O₃ 1.2 |
| | Metal composition ratio | In | 83.2 | 83.2 | 83.2 | 83.2 | 83.2 | 83.2 | 83.2 |
| | [at %] | Ga | 13.5 | 13.5 | 13.5 | 13.5 | 13.5 | 13.5 | 13.5 |
| | | Other additive elements | Al 3.3 | Al 3.3 | Al 3.3 | Al 3.3 | Al 3.3 | Al 3.3 | Al 3.3 |
| TFT | Formation of | Pressure at time of film formation [Pa] | 0.5 | 0.5 | 0.5 | 0.5 | 0.5 | 0.5 | 0.5 |
| production | channel layer | Oxygen partial pressure at time of film | 0.05 | 0.05 | 0.05 | 0.05 | 0.05 | 0.05 | 0.05 |
| conditions | | formation [Pa] | | | | | | | |
| | | Water partial pressure at time of film | 0.00 | 0.00 | 0.00 | 0.00 | 0.00 | 0.00 | 0.00 |
| | | formation [Pa] | | | | | | | |
| | | Magnetic flux density [G] | 600 | 600 | 600 | 600 | 600 | 600 | 600 |
| | | Thickness [nm] | 30 | 10 | 30 | 30 | 30 | 30 | 30 |
| | Channel layer | Semiconductor etching | Oxalic acid | Oxalic acid | Oxalic acid | Oxalic acid | Oxalic acid | Oxalic acid | Oxalic acid |
| | patterning | | | | | | | | |
| | Annealing | Temperature increase pattern [° C./min] | 10 | 10 | 10 | 10 | 10 | 10 | 10 |
| | | Highest temperature [° C.] | 350 | 350 | 350 | 350 | 350 | 350 | 350 |
| | | Retention time [hour] | 1 | 1 | 1 | 1 | 1 | 1 | 1 |
| | | Atmosphere | Atmospheric | Atmospheric | Atmospheric | Atmospheric | Atmospheric | Atmospheric | Atmospheric |
| | Channel layer | Pretreatment method | Sputtering 10 nm | Sputtering 10 nm | Sputtering 10 nm | — | Sputtering 10 nm | Sputtering 10 nm | Sputtering 10 nm |
| | pretreatment | | SiO₂ | SiO₂ | SiO₂ | | SiO₂ | SiO₂ | SiO₂ |
| | | Annealing after pretreatment | 400° C. 1 h | 400° C. 1 h | 400° C. 1 h | — | 400° C. 1 h | 400° C. 1 h | 400° C. 1 h |
| | Rare gas supply | Rare gas supply source | SiO₂:Ar+ | SiO₂:Ar+ | SiO₂:Ar+ | SiO₂:Ar+ | SiO₂:Ar+ | SiO₂:Ne+ | SiO₂:Kr+ |
| | treatment | Rare gas supply amount (thickness [nm] | 100 | 100 | 100 | 100 | 50 | 100 | 100 |
| | | or time [s] or dose amount [ions/cm²]) | | | | | | | |
| | | Rare gas supply method | Sputtering | Sputtering | Sputtering | Sputtering | Sputtering | Sputtering | Sputtering |
| | | Film formation atmosphere gas or plasma gas | Ar, O₂ | Ar, O₂ | Ar, O₂ | Ar, O₂ | Ar, O₂ | Ne, O₂ | Kr, O₂ |
| | | or injection gas | | | | | | | |
| | Formation of gate | Gate insulating film | — | — | — | — | SiO₂ | — | — |
| | insulating film | Thickness [nm] | — | — | — | — | 50 | — | — |
| | | Film forming method | — | — | — | — | CVD 350° C. | — | — |
| | | Film forming atmosphere gas | — | — | — | — | SiH4, N2O | — | — |
| | Annealing | Highest temperature [° C.] | — | — | 200 | — | — | — | — |
| | | Retention time [hour] | — | — | 1 | — | — | — | — |
| | | Atmosphere | — | — | Atmospheric | — | — | — | — |
| | Refer to Table 2 for continuation of TFT production conditions | | | | | | | | |
| | Detected rare gas | | Ar | Ar | Ar | Ar | Ar | Ne | Kr |
| | Average concentration of rare gas in crystalline oxide semiconductor | | 0.65 | 1.10 | 0.55 | 2.50 | 0.50 | 1.80 | 0.60 |
| | film [at %] | | | | | | | | |
| | Thickness of rare gas region in crystalline oxide semiconductor film [nm] | | 11.0 | 7.0 | 8.0 | 15.0 | 9.0 | 11.0 | 6.0 |
| | TFT | S value [V/dec.] | 0.82 | 0.92 | 0.80 | 1.01 | 0.35 | 1.20 | 0.90 |
| | characteristics | Initial characteristics | ◯ | ◯ | ◯ | ◯ | ◯ | ◯ | ◯ |

TABLE 1-2

| | | | Example 8 | Example 9 | Example 10 | Example 11 | Example 12 | Example 13 | Example 14 |
|---|---|---|---|---|---|---|---|---|---|
| Sputtering | Loaded composition | In₂O₃ | 89.0 | 89.0 | 89.0 | 89.0 | 100.0 | 81.6 | 81.6 |
| target | ratio [mass %] | Ga₂O₃ | 9.8 | 9.8 | 9.8 | 9.8 | 0.0 | 18.4 | 18.4 |
| | | Other additive elements | Al₂O₃ 1.2 | Al₂O₃ 1.2 | Al₂O₃ 1.2 | Al₂O₃ 1.2 | 0.0 | 0.0 | 0.0 |
| | Metal composition | In | 83.2 | 83.2 | 83.2 | 83.2 | 100.0 | 75.0 | 75.0 |
| | ratio [at %] | Ga | 13.5 | 13.5 | 13.5 | 13.5 | 0.0 | 25.0 | 25.0 |
| | | Other additive elements | Al 3.3 | Al 3.3 | Al 3.3 | Al 3.3 | 0.0 | 0.0 | 0.0 |
| TFT | Formation of | Pressure at time of film formation [Pa] | 0.5 | 0.5 | 0.5 | 0.5 | 0.5 | 0.5 | 0.5 |
| production | channel layer | Oxygen partial pressure at time of film | 0.05 | 0.05 | 0.05 | 0.05 | 0.00 | 0.00 | 0.05 |
| conditions | | formation [Pa] | | | | | | | |
| | | Water partial pressure at time of film | 0.00 | 0.00 | 0.00 | 0.00 | 0.01 | 0.01 | 0.00 |
| | | formation [Pa] | | | | | | | |
| | | Magnetic flux density [G] | 600 | 600 | 600 | 600 | 600 | 600 | 600 |
| | | Thickness [nm] | 30 | 30 | 30 | 50 | 30 | 30 | 30 |
| | Channel layer | Semiconductor etching | Oxalic acid | Oxalic acid | Oxalic acid | Oxalic acid | Oxalic acid | Oxalic acid | Oxalic acid |
| | patterning | | | | | | | | |
| | Annealing | Temperature increase pattern [° C./min] | 10 | 10 | 10 | 10 | 10 | 10 | 10 |
| | | Highest temperature [° C.] | 350 | 350 | 350 | 350 | 350 | 350 | 350 |
| | | Retention time [hour] | 1 | 1 | 1 | 1 | 1 | 1 | 1 |
| | | Atmosphere | Atmospheric | Atmospheric | Atmospheric | Atmospheric | Atmospheric | Atmospheric | Atmospheric |
| | Channel layer | Pretreatment method | — | Sputtering 10 nm | Sputtering 10 nm | Sputtering 10 nm | Sputtering 10 nm | Sputtering 10 nm | Sputtering 10 nm |
| | pretreatment | | | SiO₂ | SiO₂ | SiO₂ | SiO₂ | SiO₂ | SiO₂ |
| | | Annealing after pretreatment | — | 400° C. 1 h | 400° C. 1 h | 400° C. 1 h | 400° C. 1 h | 400° C. 1 h | 400° C. 1 h |
| | Rare gas supply | Rare gas supply source | Ar+ | Ar+ | Ar+ | Ar+ | SiO₂:Ar+ | SiO₂:Ar+ | SiO₂:Ar+ |
| | treatment | Rare gas supply amount (thickness [nm] or time | 100 s | 1 × 10¹⁵ ions/cm² | 5 × 10¹⁵ ions/cm² | 5 × 10¹⁵ ions/cm² | 100 | 100 | 100 |
| | | [s] or dose amount [ions/cm²]) | | | | | | | |
| | | Rare gas supply method | Ar Plasma | Ion Implantation | Ion Implantation | Ion Implantation | Sputtering | Sputtering | Sputtering |
| | | Film formation atmosphere gas or plasma gas | Ar | Ar | Ar | Ar | Ar, O₂ | Ar, O₂ | Ar, O₂ |
| | | or injection gas | | | | | | | |
| | Formation of gate | Gate insulating film | SiO₂ | SiO₂ | SiO₂ | SiO₂ | — | — | — |
| | insulating film | Thickness [nm] | 100 | 100 | 100 | 100 | — | — | — |
| | | Film forming method | Sputtering | Sputtering | Sputtering | Sputtering | — | — | — |
| | | Film forming atmosphere gas | Ar, O₂ | Ar, O₂ | Ar, O₂ | Ar, O₂ | — | — | — |
| | Annealing | Highest temperature [° C.] | — | 350 | 350 | 350 | — | — | — |
| | | Retention time [hour] | — | 1 | 1 | 1 | — | — | — |
| | | Atmosphere | — | Atmospheric | Atmospheric | Atmospheric | — | — | — |
| | Refer to Table 2 for continuation of TFT production conditions | | | | | | | | |
| | Detected rare gas | | Ar | Ar | Ar | Ar | Ar | Ar | Ar |
| | Average concentration of rare gas in crystalline oxide semiconductor | | 3.20 | 1.10 | 4.90 | 0.50 | 1.15 | 1.05 | 0.90 |
| | film [at %] | | | | | | | | |
| | Thickness of rare gas region in crystalline oxide semiconductor film [nm] | | 11.0 | 11.0 | 11.0 | 45.0 | 11.0 | 11.0 | 11.0 |
| | TFT | S value [V/dec.] | 1.22 | 0.75 | 1.30 | 0.32 | 0.95 | 0.80 | 0.71 |
| | characteristics | Initial characteristics | ◯ | ◯ | ◯ | ◯ | ◯ | ◯ | ◯ |

TABLE 1-3

| | | | | | | | Reference | Comparative |
|---|---|---|---|---|---|---|---|---|
| | | | Example 15 | Example 16 | Example 17 | Example 18 | Example 1 | Example 1 |
| Sputtering | Loaded composition ratio | In₂O₃ | 89.4 | 89.4 | 89.0 | 95.0 | 89.0 | 89.0 |
| target | [mass %] | Ga₂O₃ | 10.6 | 10.6 | 9.8 | 5.0 | 9.8 | 9.8 |
| | | Other additive elements | 0.0 | 0.0 | Al₂O₃ 1.2 | 0.0 | Al₂O₃ 1.2 | Al₂O₃ 1.2 |
| | Metal composition ratio | In | 85.0 | 85.0 | 83.2 | 92.8 | 83.2 | 83.2 |
| | [at %] | Ga | 15.0 | 15.0 | 13.5 | 7.2 | 13.5 | 13.5 |
| | | Other additive elements | 0.0 | 0.0 | Al 3.3 | 0.0 | Al 3.3 | Al 3.3 |
| TFT | Formation of | Pressure at time of film formation [Pa] | 0.5 | 0.5 | 0.5 | 0.5 | 0.5 | 0.5 |
| production | channel layer | Oxygen partial pressure at time of film | 0.00 | 0.05 | 0.00 | 0.00 | 0.05 | 0.05 |
| conditions | | formation [Pa] | | | | | | |
| | | Water partial pressure at time of film | 0.01 | 0.00 | 0.01 | 0.01 | 0.00 | 0.00 |
| | | formation [Pa] | | | | | | |
| | | Magnetic flux density [G] | 600 | 600 | 600 | 600 | 600 | 600 |
| | | Thickness [nm] | 30 | 30 | 30 | 30 | 30 | 30 |
| | Channel layer | Semiconductor etching | Oxalic acid | Oxalic acid | Oxalic acid | Oxalic acid | Oxalic acid | Oxalic acid |
| | patterning | | | | | | | |
| | Annealing | Temperature increase pattern [° C./min] | 10 | 10 | 10 | 10 | 10 | 10 |
| | | Highest temperature [° C.] | 350 | 350 | 350 | 350 | 350 | 350 |
| | | Retention time [hour] | 1 | 1 | 1 | 1 | 1 | 1 |
| | | Atmosphere | Atmospheric | Atmospheric | Atmospheric | Atmospheric | Atmospheric | Atmospheric |
| | Channel layer | Pretreatment method | Sputtering 10 nm | Sputtering 10 nm | Sputtering 10 nm | Sputtering 10 nm | Sputtering 10 nm | Sputtering 10 nm |
| | pretreatment | | SiO₂ | SiO₂ | SiO₂ | SiO₂ | SiO₂ | SiO₂ |
| | | Annealing after pretreatment | 400° C. 1 h | 400° C. 1 h | 400° C. 1 h | 400° C. 1 h | 400° C. 1 h | 400° C. 1 h |
| | Rare gas supply | Rare gas supply source | SiO₂:Ar+ | SiO₂:Ar+ | SiO₂: Ar+ | SiO₂:Ar+ | SiO₂:He+ | SiO₂:Ar+ |
| | treatment | Rare gas supply amount (thickness [nm] or time | 100 | 100 | 100 | 100 | 100 | 100 |
| | | [s] or dose amount [ions/cm²]) | | | | | | |
| | | Rare gas supply method | Sputtering | Sputtering | Sputtering | Sputtering | Sputtering | Sputtering |
| | | Film formation atmosphere gas or plasma gas | Ar, O₂ | Ar, O₂ | Ar, O₂ | Ar, O₂ | He, O₂ | Ar, O₂ |
| | | or injection gas | | | | | | |
| | Formation of gate | Gate insulating film | — | — | — | — | — | — |
| | insulating film | Thickness [nm] | — | — | — | — | — | — |
| | | Film forming method | — | — | — | — | — | — |
| | | Film forming atmosphere gas | — | — | — | — | — | — |
| | Annealing | Highest temperature [° C.] | — | — | — | — | — | 400 |
| | | Retention time [hour] | — | — | — | — | — | 1 |
| | | Atmosphere | — | — | — | — | — | Atmospheric |
| | Refer to Table 2 for continuation of TFT production conditions | | | | | | | |
| | Detected rare gas | | Ar | Ar | Ar | Ar | N/D | Ar |
| | Average concentration of rare gas in crystalline oxide semiconductor | | 0.85 | 0.80 | 0.75 | 0.60 | N/D | 0.3 or less |
| | film [at %] | | | | | | | |
| | Thickness of rare gas region in crystalline oxide semiconductor film [nm] | | 11.0 | 11.0 | 11.0 | 11.0 | N/D | — |
| | TFT | S value [V/dec.] | 0.67 | 0.62 | 0.55 | 0.46 | 0.90 | 0.28 |
| | characteristics | Initial characteristics | ◯ | ◯ | ◯ | ◯ | ◯ | ◯ |

TABLE 2

| | | | Examples 1 to 18, Reference |
|---|---|---|---|
| | | | Example 1, and Comparative |
| | | | Example 1 |
| TFT | Formation of gate electrode | Gate electrode | Mo |
| production | | Thickness [nm] | 150 |
| conditions | Gate patterning | Gate electrode etchant | PAN |
| (continued) | | Gate insulating film etchant | BHF |
| | | Cleaning etchant | ITO-06N |
| | Formation of ITO layer | Oxygen partial pressure at time of film | 2.0 |
| | | formation [%] | |
| | | Thickness [nm] | 2 |
| | Low-resistance annealing | Highest temperature [° C.] | 350 |
| | | Retention time [hour] | 1 |
| | | Atmosphere | Atmospheric |
| | Formation of interlayer | Insulating film | SiO₂ |
| | insulating film | Thickness [nm] | 150 |
| | Formation of contact hole in | Etchant | BHF |
| | interlayer insulating film | | |
| | Formation of electrode | Electrode | Mo |
| | Final annealing | Highest temperature [° C.] | 300 |
| | | Retention time [hour] | 1 |
| | | Atmosphere | N₂ |

As shown in Tables 1-1 to 1-3, the TFTs of Examples 1 to 3, 5, 7, and 12 to 18, in which the rare gas region was formed in the crystalline oxide semiconductor film by forming a film on the surface of the crystalline oxide semiconductor film through the channel layer pretreatment, followed by forming a film as the rare gas supply source by sputtering, had an average rare gas concentration in the crystalline oxide semiconductor film of 0.5 at % or more and less than 5 at %, and had an appropriate S value of 0.8±0.5 V/dec, exhibited excellent gradation performance, and also had excellent initial characteristics.

The TFT of Example 4, in which the channel layer pretreatment was not performed, the film serving as a rare gas source (the film functioning as a gate insulating film) was formed by sputtering, and annealing was not performed, also had an average rare gas concentration of 2.5 at % in the crystalline oxide semiconductor film and an appropriate S value of 0.8±0.5 V/dec, and exhibited excellent gradation performance and excellent initial characteristics.

The TFT of Example 8, in which the channel layer pretreatment was not performed, the rare gas supply treatment was performed by plasma treatment, a gate insulating film was formed, and the gate insulating film was not annealed, had the average rare gas concentration in the crystalline oxide semiconductor film of 3.20 at %, and the S value of an appropriate value of 0.8±0.5 V/dec, and the gradation performance was excellent, and the initial characteristics were also excellent.

In addition, the TFTs of Examples 9 to 11, in which a channel layer pretreatment was performed, the rare gas supply treatment was performed by ion implantation, the gate insulating film was formed by sputtering, and annealing was performed, had the average rare gas concentration in the crystalline oxide semiconductor film of 0.5 at % or more and less than 5 at %, and the S value of an appropriate value of 0.8±0.5 V/dec, and the gradation performance was excellent, and the initial characteristics were also excellent.

In comparison with the TFT of Examples, it can be seen that the TFT of Comparative Example 1, in which after performing the channel layer pretreatment and the rare gas supply treatment by sputtering, the resulting film (which will became the gate insulating film) was annealed, had the average rare gas concentration in the crystalline oxide semiconductor film of as low as 0.3 at % or less, and the S value of also as low as 0.28. This is considered for the reason that the rare gas was dissipated from the crystalline oxide semiconductor film by annealing the film serving as the rare gas supply source.

As to the TFT of Reference Example 1, in which the film was formed on the surface of the crystalline oxide semiconductor film by the channel layer pretreatment, and then the film as a rare gas supply source was formed by sputtering using He as an atmospheric gas, as described above, He cannot be detected by EDX analysis, and therefore the He concentration in the crystalline oxide semiconductor film cannot be measured. However, it was confirmed by SIMS analysis that the crystalline oxide semiconductor film contained He. In the evaluation of the TFT characteristics, the S value was 0.90, and the initial characteristics were also good. Therefore, it is estimated that there is a high probability that the crystalline oxide semiconductor film has a region in which the He concentration is in the range of 0.5 at % or more and less than 5 at %, and which is continuous in the film thickness direction.

### INDUSTRIAL APPLICABILITY

The laminate structure of the present disclosure can be suitably used as a constituent member of a thin film transistor, for example, a channel layer and a gate insulating film. In addition, the thin film transistor of the present disclosure including the laminate structure of the present disclosure can be used in an electric circuit to be used in an electric device, an electronic device, a vehicle, or a power engine.

Some embodiments and/or Examples of the present disclosure have been described above in detail, but it is easy for a person skilled in the art to add a large number of modifications to these illustrative embodiments and/or Examples without substantially departing from the novel teachings and effects of the present disclosure. Thus, the large number of modifications are encompassed in the scope of the present disclosure.

The literatures described herein and the contents of the applications based on which the priority under the Paris Convention of the present application is claimed are incorporated herein in their entirety.

1. A laminate structure, comprising:
a crystalline oxide semiconductor film containing In as a main component; and
an insulating film laminated in contact with the crystalline oxide semiconductor film,
wherein the crystalline oxide semiconductor film has one or more regions continuing 3 nm or more in the film thickness direction and the region has a rare gas concentration within a range of 0.5 at % or more and less than 5 at %.

2. The laminate structure according to claim 1, wherein the crystalline oxide semiconductor film has one or more regions continuing 5 nm or more in the film thickness direction.

3. The laminate structure according to claim 1, wherein the rare gas is argon.

4. The laminate structure according to claim 1, wherein the insulating film is any one of an oxide film containing silicon (Si) as a main component, a nitride film containing silicon (Si) as a main component, and an oxynitride film containing silicon (Si) as a main component.

5. The laminate structure according to claim 1, wherein the insulating film is an oxide film containing silicon (Si) as a main component.

6. The laminate structure according to claim 1, wherein the crystalline oxide semiconductor film further contains Ga.

7. The laminate structure according to claim 1, wherein the crystalline oxide semiconductor film further contains one or more kinds of additive elements selected from B, Al, Si, Sc, Zn, Ge, Y, Zr, Sn, Sm, and Yb.

8. The laminate structure according to claim 1, wherein an atomic ratio of In with respect to all metal elements contained in the crystalline oxide semiconductor film ([In]/([In]+[all metal elements except In])×100) is 62 at % or more.

9. The laminate structure according to claim 6, wherein an atomic ratio of Ga with respect to all metal elements contained in the crystalline oxide semiconductor film ([Ga]/([Ga]+[all metal elements except Ga])×100) is 30 at % or less.

10. The laminate structure according to claim 7, wherein an atomic ratio of a total amount of the additive elements with respect to all metal elements contained in the crystalline oxide semiconductor film ([total amount of additive elements]/([total amount of additive elements]+[all metal elements except additive elements])×100) is 10 at % or less.

11. The laminate structure according to claim 1, wherein the crystalline oxide semiconductor film has a carrier concentration of 1×10¹⁸ cm⁻³ or less.

12. The laminate structure according to claim 1, wherein the crystalline oxide semiconductor film contains a crystal grain having a bixbyite structure.

13. A thin film transistor, comprising the laminate structure of claim 1,
wherein the thin film transistor includes:
a channel layer;
a source electrode and a drain electrode each connected to the channel layer; and
a gate electrode laminated on the channel layer through intermediation of a gate insulating film,
wherein the channel layer is the crystalline oxide semiconductor film in the laminate structure, and
wherein the gate insulating film is the insulating film in the laminate structure.

14. The thin film transistor according to claim 13, wherein the thin film transistor is a top-gate type transistor.

15. A semiconductor element, comprising the laminate structure of claim 1.

16. A diode, a thin film transistor, a MOSFET, or a MESFET, comprising the semiconductor element of claim 15.

17. An electronic circuit, comprising the diode, the thin film transistor, the MOSFET, or the MESFET of claim 16.

18. An electric device, an electronic device, a vehicle, or a power engine, comprising the electronic circuit of claim 17.
